(19) United States
(12) Patent Application Publication
(10) Pub. No.: US 2024/0319387 A1
(43) Pub. Date: Sep. 26, 2024

(54) BENDABLE DETECTOR

(71) Applicant: Vieworks Co., Ltd., Anyang-si (KR)

(72) Inventor: Jungmin CHOI, Ansan-si (KR)

(21) Appl. No.: 18/604,692

(22) Filed: Mar. 14, 2024

(30) Foreign Application Priority Data
Mar. 23, 2023 (KR) 10-2023-0038119

(51) Int. Cl. G01T 1/20; H01R 13/24; H05K 5/02

(52) U.S. Cl. CPC G01T 1/20188; H01R 13/2471; H05K 5/0221

(57) ABSTRACT

A bendable detector comprises: a first housing comprising a control unit therein and made of an inelastic material or a material having higher rigidity than a material of a second housing; the second housing comprising a detection panel therein and made of an elastic material or composite material including an elastic material and an inelastic material; and a connection mechanism having a connection structure configured to couple the first housing and the second housing so that the first housing and the second housing are separable.

### CROSS-REFERENCE TO RELATED APPLICATIONS

This application claims priority to and the benefit of Korean Patent Application No. 10-2023-0038119 filed in the Korean Intellectual Property Office on Mar. 23, 2023, the entire contents of which are incorporated herein by reference.

### TECHNICAL FIELD

The present invention relates to a bendable detector used to inspect materials, performance, states, whether a defect is present, and the like without destroying test targets.

### BACKGROUND ART

A non-destructive testing method refers to a method that inspects materials, performance, states, whether a defect is present, and the like without destroying test targets.

The non-destructive testing method may be used to identify an internal structure or a defect without destroying the test target. For example, the non-destructive testing method may be used to inspect quality of various types of industrial products in industrial sites, identify whether buildings and the like are defective, and identify abrasion/corrosion states.

In case that non-destructive testing is performed by using X-rays among the non-destructive testing methods, a hollow cylindrical object, e.g., a pipe may be a subject of a test target.

For example, Korean Patent No. 10-2373241 discloses a radioactive ray detector including a flexible radioactive ray detection panel, and a bending supporter part configured to support the radioactive ray detection panel. However, a bendable detector in the related art has a structure vulnerable to water and dust, and a mechanism and device for supporting the detector are complicated. Further, there is a problem in that the entire detector cannot be used when the radioactive ray detection panel is broken down.

### SUMMARY OF THE INVENTION

The present invention has been made in an effort to provide a bendable detector that may have waterproof and/or dustproof performance improved by improving a bendable detector in the related art and have a detection panel that may detect radioactive rays and be easily replaced and used.

The present invention provides a bendable detector including: a first housing including a control unit therein and made of an inelastic material or a material having higher rigidity than a material of a second housing; the second housing including a detection panel therein and made of an elastic material or composite material including an elastic material and an inelastic material; and a connection mechanism having a connection structure configured to couple the first housing and the second housing so that the first housing and the second housing are separable.

In addition, the bendable detector may include: a first connector provided on a first opposing surface of the first housing; and a second connector provided on a second opposing surface of the second housing and configured to be connected to the first connector.

In addition, any one of the first and second connectors may be a connector having a pogo pin, and the other of the first and second connectors may be a connector to which the pogo pin is connected.

In the embodiment, the connection mechanism may be a first connection mechanism including: an insertion member protruding from one side or two opposite sides of the first opposing surface of the first housing toward the second opposing surface of the second housing; and an insertion hole provided in a portion of the second opposing surface of the second housing corresponding to the insertion member so that the insertion member is inserted into the insertion hole.

In the embodiment, the connection mechanism may be a first connection mechanism including: an insertion member protruding from one side or two opposite sides of the second opposing surface of the second housing toward the first opposing surface of the first housing; and an insertion hole provided in a portion of the first opposing surface of the first housing corresponding to the insertion member so that the insertion member is inserted into the insertion hole.

In addition, the first connection mechanism may include a locking member configured to prevent the first and second housings from being disconnected, a guide hole may be formed in the second housing in a direction intersecting the insertion hole, one end of the locking member may be elastically supported by an elastic member provided in the guide hole, the other end of the locking member may be inserted into an insertion groove provided in the insertion member and restrict a movement of the insertion member, and a locking adjustment device connected to the locking member may move the locking member while moving along an operating space provided in the second housing.

In the embodiment, the connection mechanism may be a second connection mechanism including: an insertion member protruding from one side or two opposite sides of the first opposing surface of the first housing toward the second opposing surface of the second housing; and an insertion groove provided in a lateral surface of the second housing corresponding to the insertion member and formed in a longitudinal direction so that the insertion member is inserted into the insertion groove.

In addition, the insertion member and the insertion groove may each have a shape such as a “ [symbol] ” shape or a “⊏” shape.

In the embodiment, the connection mechanism may include an insertion member configured to prevent the first and second housings from being disconnected, the insertion member may include an extension portion protruding from one side or two opposite sides of the first opposing surface of the first housing toward the second opposing surface of the second housing, and a locking member provided at an end of the extension portion, an insertion groove may be provided in a portion of the second opposing surface of the second housing corresponding to the insertion member, the insertion member may be inserted into the insertion groove, a locking adjustment device connected to the extension portion may be provided, the locking adjustment device may be accommodated in an accommodation portion of the first housing, at least a part of the locking adjustment device may be exposed to the outside of the accommodation portion, and the locking adjustment device may rotate to rotate the locking member in a locking direction, in a state in which the insertion member is inserted into the insertion groove, so that the locking member intersects the insertion groove.

In the embodiment, the connection mechanism may be a fifth connection mechanism including: a locking member provided on one side surface or two opposite surfaces of the first housing and including an extension portion having one end connected to the first housing by a hinge shaft, the extension portion being configured to rotate about the hinge shaft and elastically supported by an elastic member coupled to the hinge shaft, and a catching projection provided at the other end of the extension portion; and an insertion groove provided in a lateral surface of the second housing corresponding to the locking member and formed in a longitudinal direction so that the extension portion is inserted into the insertion groove.

In addition, the catching projection may be inserted into a catching groove provided in the insertion groove.

In addition, the fifth connection mechanism may further include: an insertion member provided between the locking members disposed at two opposite sides, the insertion member protruding from one side or two opposite sides of the first opposing surface of the first housing toward the second opposing surface of the second housing; and an insertion hole provided in a portion of the second opposing surface of the second housing corresponding to the insertion member so that the insertion member is inserted into the insertion hole.

In the embodiment, the connection mechanism may be a sixth connection mechanism having a connection member coupled while penetrating the first and second housings in a state in which the first and second housings are disposed side by side horizontally in a longitudinal direction.

In the embodiment, the connection mechanism may be a seventh connection mechanism having a connection member coupled while penetrating the first and second housings in a state in which the first and second housings are arranged vertically.

In addition, the seventh connection mechanism may further include: a sliding groove provided in a lower portion of the first housing; and a sliding rail provided on an upper portion of the second housing so as to conform to the sliding groove and slidably inserted into the sliding groove.

In the embodiment, the connection mechanism may be an eighth connection mechanism in which connection plates configured to connect the first housing and the second housing are attached to two opposite sides of the first housing and two opposite sides of the second housing in a state in which the first and second housings are disposed side by side horizontally in a longitudinal direction or arranged vertically, first connection members are coupled to the first housing while penetrating the connection plates, and second connection members are coupled to the second housing while penetrating the connection plates.

In the embodiment, the connection mechanism may be a ninth connection mechanism including: a sliding groove provided in a lower portion of the first housing and formed in a longitudinal direction; and a sliding rail provided on an upper portion of the second housing and formed in the longitudinal direction, the sliding rail conforming to the sliding groove so that the sliding rail is slidably inserted into the sliding groove.

In addition, the ninth connection mechanism may further include: a guide hole provided in the first housing and formed in a direction intersecting the sliding groove; a locking member having one end elastically supported by an elastic member inserted into the guide hole, and the other end inserted into a insertion groove provided in the sliding rail; and a locking adjustment device connected to the locking member and configured to move the locking member while moving along an operating space provided in the first housing.

In the embodiment, the connection mechanism may be a tenth connection mechanism including: a sliding rail provided on one longitudinal surface of the first housing and formed in a direction intersecting a longitudinal direction of the first housing; and a sliding groove provided in one longitudinal surface of the second housing and formed in a direction intersecting a longitudinal direction of the second housing so that the sliding rail is inserted into the sliding groove.

In addition, a first opposing surface, on which a first connector is provided, may be provided on a surface that enters the sliding groove of the sliding rail, and a second opposing surface, on which a second connector is provided, may be provided on an inner end surface of the sliding groove corresponding to the first opposing surface.

In addition, the first opposing surface may be provided in the direction intersecting the longitudinal direction of the first housing, and the second opposing surface may be provided in the direction intersecting the longitudinal direction of the second housing.

In addition, the first connector may be provided in the direction intersecting the longitudinal direction of the first housing, and the second connector may be provided in the direction intersecting the longitudinal direction of the second housing.

In addition, a first opposing surface, on which a first connector is provided, may be provided in an accommodation groove provided in a longitudinal direction of one surface of the sliding rail, and a second opposing surface, on which a second connector is provided, may be provided in the sliding groove while corresponding to the first opposing surface.

In addition, the first opposing surface may be provided in the direction identical to the longitudinal direction of the first housing, and the second opposing surface may be provided in the direction identical to the longitudinal direction of the second housing.

In addition, the first connector may be provided in the direction identical to the longitudinal direction of the first housing, and the second connector may be provided in the direction identical to the longitudinal direction of the second housing.

In addition, the first connector and the second connector may each be configured as a horizontal connector or an inclined connector.

In addition, the tenth connection mechanism may further include: a guide hole provided in the second housing and configured to communicate with the sliding groove; a locking member having one end elastically supported by an elastic member provided in the guide hole, and the other end inserted into an insertion groove of the first housing; and a locking adjustment device connected to the locking member and configured to move the locking member while moving along an operating space provided in the second housing.

In the embodiment, the connection mechanism may be an eleventh connection mechanism including: an assembling groove provided in an upper portion of the first opposing surface of the first housing; a locking member including an extension portion having one end positioned in the first housing, rotatably connected to the first housing by a hinge shaft, and elastically supported by an elastic member, and the other end exposed toward the second housing, and a catching projection provided at the other end of the extension portion; at least one hook inserted into the assembling groove and provided on a portion of the second opposing surface of the second housing while corresponding to the assembling groove; an insertion groove formed in a bottom surface of the second housing so that the other end of the extension portion is inserted into the insertion groove; and a catching groove provided in the insertion groove so that the catching projection is inserted into the catching groove.

In the embodiment, the connection mechanism may be a twelfth connection mechanism including: an insertion hole provided at one side of the first opposing surface of the first housing; a catching groove provided at the other side of the first opposing surface of the first housing and configured as a concave groove formed in a direction from a bottom surface of the first housing toward an upper surface of the first housing; an insertion member protruding from one side of the second opposing surface of the second housing toward the first housing and inserted into the insertion hole; and a catching member protruding from the other side of the second opposing surface of the second housing toward the first housing, the catching member being configured to be inserted into the catching groove while rotating about the insertion member inserted into the insertion hole in the direction from the bottom surface of the first housing toward the upper surface of the first housing.

In addition, the insertion hole may include: a first insertion hole configured as a long hole; and a second insertion hole configured to communicate with the first insertion hole and provided to be closer to the inside of the first housing than the first insertion hole, the second insertion hole being configured as a hole having the same center as the first insertion hole. In addition, the insertion member may include: a first insertion member positioned in the first insertion hole when the insertion member is inserted into the insertion hole; and a second insertion member provided at an end of the first insertion member and having a shape conforming to the first insertion hole, the second insertion member being configured to rotate to intersect the first insertion hole in a state in which the second insertion member is inserted into the second insertion hole through the first insertion hole.

In addition, the catching groove may include: a first catching groove; and a second catching groove configured to communicate with the first catching groove and provided to be closer to the inside of the second housing than the first catching groove, the second catching groove being configured as a groove larger than the first catching groove.

In addition, at least one lateral surface of the first catching groove may be configured as an inclined surface, and the inclined surface may have an inclined structure having a width that decreases in the direction from the bottom surface of the first housing toward the upper surface of the first housing.

In addition, the catching member may include: a first catching member positioned in the first catching groove when the catching member is inserted into the catching groove; and a second catching member provided at an end of the first catching member and configured such that a portion of the second catching member, which is directed toward the bottom surface of the first housing in a state in which the second catching member is inserted into the second catching groove, is configured as a flat surface portion.

In addition, the twelfth connection mechanism may further include: a guide hole provided in the first housing and formed in a direction intersecting the second catching groove so as to communicate with the second catching groove; a locking member having one end inserted into the guide hole and elastically supported by an elastic member, and the other end configured to support the flat surface portion of the second catching member inserted into the second catching groove to implement a locked state; and a locking adjustment device connected to the locking member and configured to move the locking member in a locking direction while moving along an operating space provided in the first housing.

According to the present invention, the first housing, which includes the control unit, and the second housing, which includes the radioactive ray detection panel, may be separably coupled, such that the second housing including the radioactive ray detection panel may be replaced and used, as necessary.

In addition, according to the present invention, the second housing, which includes the radioactive ray detection panel, may be made of a flexible material and configured to surround the radioactive ray detection panel, such that the waterproof and/or dustproof characteristics may be improved.

In addition, according to the present invention, the connection mechanism having at least one connection structure may be provided between the first housing and the second housing, such that the first connector of the first housing and the second connector of the second housing may be kept securely connected, and the first housing and the second housing may be kept securely connected.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is an exploded perspective view illustrating a first housing and a second housing according to a first embodiment of the present invention.

FIG. 2 is a perspective view illustrating the second housing according to the first embodiment of the present invention.

FIG. 3 is a top plan view illustrating the second housing according to another embodiment of FIG. 1, i.e., a partial cross-sectional view illustrating a locking member.

FIG. 4 is a top plan view illustrating a state in which the first housing and the second housing according to another embodiment of FIG. 1 are connected.

FIG. 5 is a top plan view illustrating the first housing and the second housing according to another embodiment of FIG. 1, i.e., a partial cross-sectional view illustrating a state in which the locking member is inserted into an insertion groove of an insertion member.

FIG. 6 is an exploded perspective view illustrating a first housing and a second housing according to a second embodiment of the present invention.

FIG. 7 is an exploded perspective view illustrating a first housing and a second housing according to a third embodiment of the present invention.

FIG. 8 is a top plan view illustrating a first housing according to a fourth embodiment of the present invention.

FIG. 9 is an enlarged view illustrating an insertion member according to the fourth embodiment of the present invention.

FIG. 10 is a front view illustrating a second housing according to the fourth embodiment of the present invention.

FIG. 11 is a top plan view illustrating a first housing according to a fifth embodiment of the present invention.

FIG. 12 is a view illustrating an elastic member coupled to a hinge shaft according to the fifth embodiment of the present invention.

FIG. 13 is a front view illustrating a second housing according to the fifth embodiment of the present invention.

FIG. 14 is a side view illustrating a state in which a first housing and a second housing according to a sixth embodiment of the present invention are connected horizontally.

FIG. 15 is a side view illustrating a state in which a first housing and a second housing according to a seventh embodiment of the present invention are connected vertically.

FIG. 16 is a front view illustrating the state in which the first housing and the second housing according to the seventh embodiment of the present invention are connected vertically.

FIG. 17 is a side view illustrating a state in which a first housing and a second housing according to an eighth embodiment of the present invention are connected vertically.

FIG. 18 is a front view illustrating the state in which the first housing and the second housing according to the eighth embodiment of the present invention are connected vertically.

FIG. 19 is a side view illustrating a state in which the first housing and the second housing according to another embodiment of FIG. 18 are connected horizontally.

FIG. 20 is a front view illustrating the state in which the first housing and the second housing according to the eighth embodiment of the present invention are connected horizontally.

FIG. 21 is a view illustrating a process of connecting a first housing and a second housing according to a ninth embodiment of the present invention.

FIG. 22 is a front view illustrating the second housing according to the ninth embodiment of the present invention.

FIG. 23 is a front view illustrating the first housing according to the ninth embodiment of the present invention.

FIG. 24 is an exploded perspective view illustrating a first housing and a second housing according to a tenth embodiment of the present invention when viewed from the second housing.

FIG. 25 is an exploded perspective view illustrating the first housing and the second housing according to the tenth embodiment of the present invention when viewed from the first housing.

FIG. 26 is a perspective view illustrating a second opposing surface of the second housing according to the tenth embodiment of the present invention.

FIG. 27 is a view illustrating a first opposing surface of the first housing according to the tenth embodiment of the present invention.

FIG. 28 is a view illustrating an inclined second connector according to the tenth embodiment of the present invention.

FIG. 29 is a top plan view illustrating a state in which the first housing and the second housing according to the tenth embodiment of the present invention are connected.

FIG. 30 is a cross-sectional view taken along line A-A in FIG. 29.

FIG. 31 is a side view illustrating a process of connecting a first housing and a second housing according to an eleventh embodiment of the present invention.

FIG. 32 is a perspective view illustrating a state in which a first housing and a second housing according to a twelfth embodiment of the present invention are separated.

FIG. 33 is a side view illustrating the state in which the first housing and the second housing according to the twelfth embodiment of the present invention are separated.

FIG. 34 is a top plan view illustrating a state in which the first housing and the second housing according to the twelfth embodiment of the present invention are connected.

FIG. 35 is a cross-sectional view taken along line B-B in FIG. 34.

FIG. 36 is a front view illustrating the first housing according to the twelfth embodiment of the present invention.

FIG. 37 is a front view illustrating the second housing according to the twelfth embodiment of the present invention.

FIG. 38 is a view illustrating a process of connecting the first housing and the second housing according to the twelfth embodiment of the present invention.

It should be understood that the appended drawings are not necessarily to scale, presenting a somewhat simplified representation of various features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout the several figures of the drawing.

### DETAILED DESCRIPTION

Hereinafter, exemplary embodiments of the present invention will be described in detail with reference to the accompanying drawings. First, in assigning reference numerals to constituent elements of the respective drawings, it should be noted that the same constituent elements will be designated by the same reference numerals, if possible, even though the constituent elements are illustrated in different drawings. In addition, in the description of the present invention, the specific descriptions of publicly known related configurations or functions will be omitted when it is determined that the specific descriptions may obscure the subject matter of the present invention. Further, the exemplary embodiments of the present invention will be described below, but the technical spirit of the present invention is not limited thereto and may of course be modified and variously carried out by those skilled in the art.

A first housing and a second housing of the present invention may be connected by any one connection mechanism among first to twelfth connection mechanisms each having at least one connection structure.

The present invention may include the first housing and the second housing. A control unit (not illustrated) including components, such as a printed board assembly (PBA) and a battery, may be mounted in the first housing. The first housing may be made of an inelastic material or a material having higher rigidity than a material of the second housing. For example, the first housing may be made of a metallic material such as aluminum, stainless steel, or magnesium or made of an inelastic carbon composite material or the like.

The second housing may be made of an elastic material. Alternatively, the second housing may be mostly made of an elastic material or partially made of an inelastic material.

For example, at least a part of the second housing may be made of an elastic material such as rubber, urethane, silicone, carbon composite material, or plastic that may transmit radioactive rays and change in shape. A detection panel (not illustrated) made of a flexible material may be provided in the second housing.

For example, the detection panel may be a flexible thin film transistor (TFT) panel and obtain image information by converting light, which is emitted from the fluorescent material, into electric signals (electric charges) in response to radioactive rays that penetrate the test target. In addition, the detection panel may include a readout IC (ROIC) sensor provided in the form of a chip-on-film (COF), and a gate sensor. The ROIC sensor and the gate sensor may each be made of a flexible material or have a variable structure. The second housing may be mounted on an outer peripheral surface of a test target having a curved surface, and a non-destructive test may be performed on the test target.

The second housing is configured such that a second connector is exposed to the outside in a state in which the detection panel or the like is accommodated in the second housing. Therefore, the detection panel may be completely sealed, which may improve waterproof and/or dustproof performance.

A first opposing surface of the first housing and a second opposing surface of the second housing may be disposed to face each other so that the first housing and the second housing may be connected. When the first housing and the second housing are connected, a first connector provided on the first opposing surface and the second connector provided on the second opposing surface may be connected to each other.

When the first housing and the second housing are connected, the first housing and the second housing may be positioned adjacent to each other so that the first opposing surface and the second opposing surface are tightly attached to each other or the first opposing surface and the second opposing surface face each other while being spaced apart from each other by an interval corresponding to the protruding connector.

For example, any one of the first and second connectors may be a male connector, and the other of the first and second connectors may be a female connector. For example, any one of the first and second connectors may be a connector having a pin, and the other of the first and second connectors may be a connector to which the pin is connected. For example, the first connector may be a connector having a pogo pin PP, and the second connector may be a magnetic connector to which the pogo pin PP may be connected.

According to the present invention, the first and second housings are coupled or separably provided, such that any one of the first and second housings may be easily replaced and used, as necessary.

For example, because the detection panel is used in a state in which the detection panel is curved and disposed on an outer surface of the test target, the second housing in which the detection panel is disposed may be damaged first when the detection panel is used repeatedly in comparison with the first housing in which the control unit is embedded. Alternatively, in case that the test targets have different sizes, the second housings having detection panels with different sizes may be required. In this case, the present invention enables different second housings to be coupled to the first housing and used.

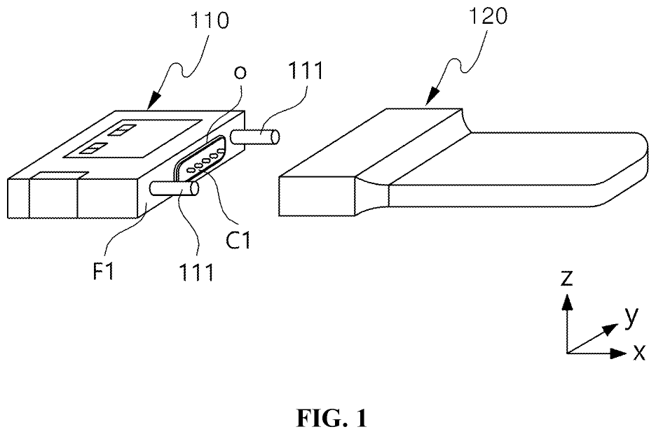

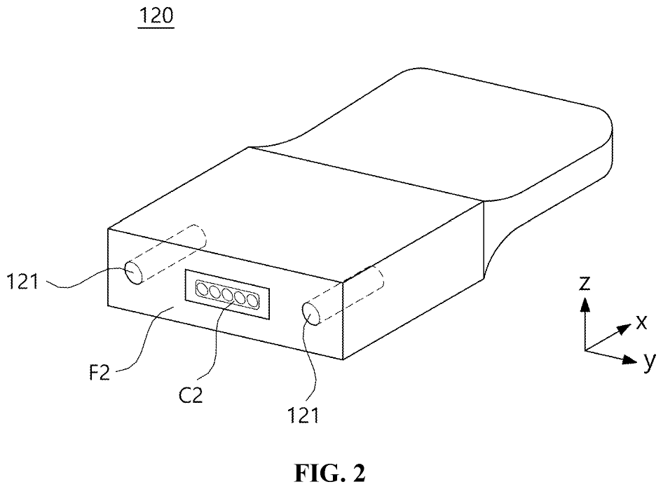

FIG. 1 is an exploded perspective view illustrating a first housing and a second housing according to a first embodiment of the present invention, and FIG. 2 is a perspective view illustrating the second housing according to the first embodiment of the present invention.

As illustrated in FIGS. 1 and 2, in the first embodiment of the present invention, a first housing 110 and a second housing 120 may be connected by a first connection mechanism. In addition, although not illustrated, a fixing means (e.g., fixing band) may be provided on the first housing 110 and the second housing 120 and fix a bendable detector, which includes the first housing 110 and the second housing 120, to a test target.

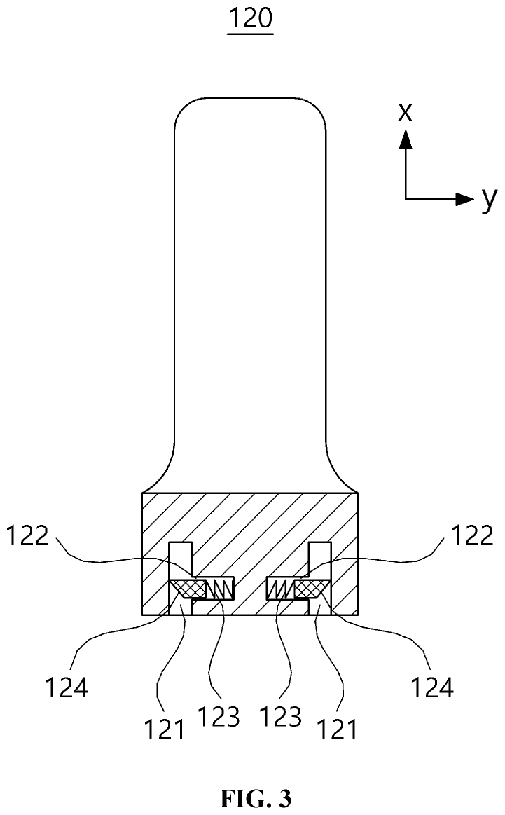

This configuration is described with reference to FIGS. 1 and 2. The first housing 110 and the second housing 120 may be connected without a locking member 124 illustrated in FIG. 3. As illustrated in FIGS. 1 and 2, the first housing 110 and the second housing 120 may be connected when insertion members 111 are inserted into insertion holes 121.

A configuration for locking the first housing 110 and the second housing 120 will be described with reference to FIGS. 3 to 5.

With reference to FIGS. 3 to 5, the first connection mechanism may include the insertion members 111, the insertion holes 121 into which the insertion members 111 are inserted, guide holes 122, the locking members 124 provided in the guide holes 122, and locking adjustment devices 126 configured to move the insertion members 111 in a locking direction.

The first housing 110 and the second housing 120 may be connected in a state in which the first housing 110 and the second housing 120 are disposed side by side horizontally in a longitudinal direction (an x-axis direction).

A first connector C1 and a second connector C2 may be provided on a first opposing surface F1 of the first housing 110 and a second opposing surface F2 of the second housing 120 that face each other.

According to the first embodiment, the first connector C1 and the second connector C2 may be connected to each other when the first housing 110 and the second housing 120 are connected. The first and second connectors C1 and C2 may be provided on one longitudinal surface of the first housing 110 and one longitudinal surface of the second housing 120 so that the first and second connectors C1 and C2 face each other. The first connector C1 and the second connector C2 may be positioned in the x-axis direction.

A sealing member O may be provided on the first opposing surface F1 of the first housing 110 or the second opposing surface F2 of the second housing 120. The sealing member O may provide a sealing structure between the first opposing surface F1 and the second opposing surface F2.

The sealing member O may prevent moisture or dust from penetrating into the first housing 110 and the second housing 120 when the first housing 110 and the second housing 120 are connected.

For example, the sealing member O may be configured to surround a periphery of the first connector C1. For example, the sealing member O may be an O-ring, a gasket, or the like that provides waterproofness.

According to the first embodiment, the insertion members 111 may be provided on the first opposing surface F1. The insertion members 111 may be provided at both sides of the first opposing surface F1 with the first connector C1 interposed therebetween. The insertion member 111 may be provided only at any one of left and right sides of the first connector C1. However, the insertion members 111 may be provided at the two opposite sides of the first connector C1 so that the first housing 110 and the second housing 120 are securely connected.

In case that the insertion members 111 are provided on the first opposing surface F1, the insertion members 111 may protrude toward the second opposing surface F2 of the second housing 120.

The insertion member 111 may have various shapes, such as a circular shape or a polygonal shape, that conform to the insertion hole 121.

In the first embodiment, the insertion holes 121 provided in the second housing 120 may correspond in number to the insertion members 111.

The insertion holes 121 may be provided at both sides of the second opposing surface F2 of the second housing 120 with the second connector C2 interposed therebetween. The insertion hole 121 may be configured as a hole into which the insertion member 111 may be inserted. The insertion hole 121 may have various shapes, such as a circular shape or a polygonal shape, that conform to the insertion member 111.

FIGS. 1 and 2 illustrate that the insertion member 111 is provided on the first housing 110, and the insertion hole 121 is provided in the second housing 120. However, the present invention is not necessarily limited thereto. On the contrary, the insertion hole 121 may be provided in the first housing 110, and the insertion member 111 may be provided on the second housing 120.

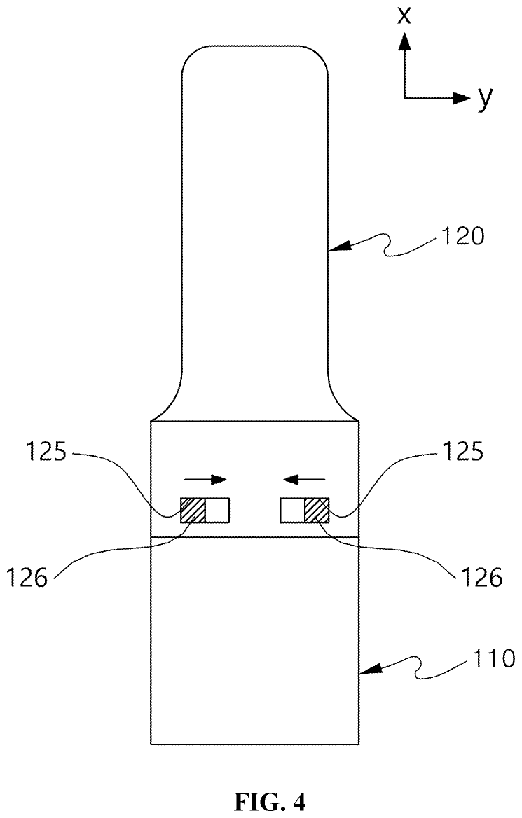

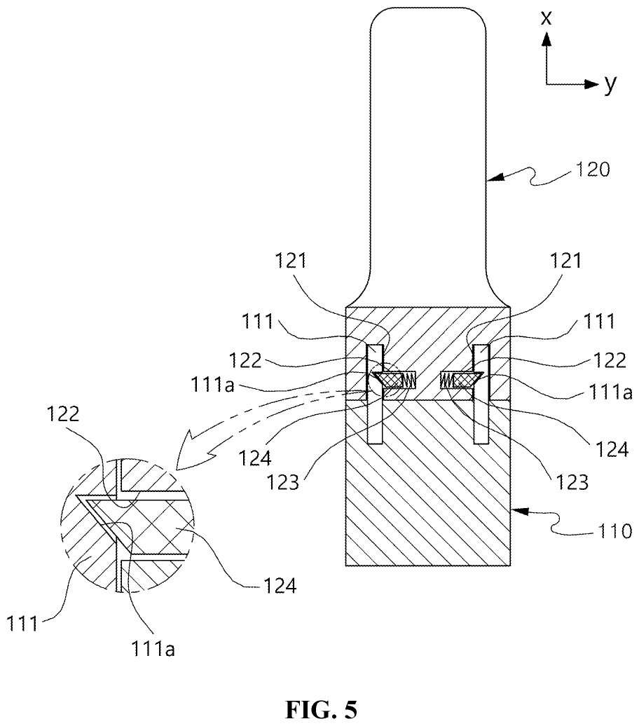

FIG. 3 is a top plan view illustrating the second housing according to another embodiment of FIG. 1, i.e., a partial cross-sectional view illustrating a locking member, FIG. 4 is a top plan view illustrating a state in which the first housing and the second housing according to another embodiment of FIG. 1 are connected, and FIG. 5 is a top plan view illustrating the first housing and the second housing according to another embodiment of FIG. 1, i.e., a partial cross-sectional view illustrating a state in which the locking member is inserted into an insertion groove of an insertion member.

As illustrated in FIGS. 3 to 5, in case that the insertion hole 121 is formed in the second housing 120, the locking member 124 may be inserted into the second housing 120. The locking member 124 is inserted into the guide hole 122 provided in the second housing 120. The guide hole 122 may be formed in a direction (e.g., a y-axis direction) intersecting the insertion hole 121 so that the guide hole 122 is provided in the second housing 120 and communicates with the insertion hole 121.

As illustrated, one end of the locking member 124, which is inserted into the guide hole 122, may be elastically supported by an elastic member 123. Alternatively, although not illustrated, one end of the locking member 124, which is inserted into the guide hole 122, may be supported by a stationary switch button or a lever. For example, the elastic member 123 may be a coiled spring.

In a state in which the insertion member 111 is inserted into the insertion hole 121, the other end of the locking member 124 may be inserted into an insertion groove 111a provided in the insertion member 111 by an elastic force of the elastic member 123. When the other end of the locking member 111 is inserted into the insertion groove 111a of the insertion member 111, the movement of the insertion member 111 may be restricted. FIG. 5 illustrates a state in which the other end of the locking member 111 is inserted into the insertion groove 111a.

The insertion groove 111a of the insertion member 111 may be formed as a groove that conforms to the other end of the locking member 124 (see FIG. 5).

As illustrated in FIG. 3, when the insertion member 111 is inserted into the insertion hole 121 in the state in which the other end of the locking member 124 is positioned in the insertion hole 121, the locking member 124 is pushed toward the guide hole 122 by the insertion member 111, such that the other end of the locking member 124 may be inserted into the insertion groove 111a provided in the insertion member 111, as illustrated in FIG. 5. For example, as illustrated in FIG. 5, one surface of the other end of the locking member 124, which is directed toward the insertion member 111, may be configured as an inclined surface, such that the locking member 124 may be easily pushed by the insertion member 111.

As another embodiment, as illustrated in FIGS. 3 to 5, the locking adjustment device 126 may operate to insert the insertion member 111 into the insertion hole 121 in the state in which the locking member 124 is completely inserted into the guide hole 122. For example, the locking adjustment device 126 may be a lever, a switch, a button, or the like.

The locking adjustment device 126 may be connected to the locking member 124. The locking adjustment devices 126 may move along operating spaces 125 provided in the second housing 120.

For example, a locked state may be released by moving the locking adjustment device 126 in an unlocking direction in a locked state in which the other end of the locking member 124 is inserted into the insertion groove 111a of the insertion member 111 by the elastic force of the elastic member 123, as illustrated in FIG. 5.

As another embodiment, the elastic member 123 may be excluded, and the locking adjustment device 126 may operate to perform the locking or unlocking operation by forcibly moving the locking member 124. Specifically, the locking adjustment device 126 may operate the insertion member 111 into the insertion hole 121 in the state in which the locking member 124 connected to the locking adjustment device 126 is completely inserted into the guide hole 122. Further, the locking adjustment device 126 may operate to move the locking member 124, which is connected to the locking adjustment device 126, in the locking direction so that the locking member 124 is fitted into the insertion groove 111a provided in the insertion member 111, as illustrated in the enlarged view of FIG. 5.

Because the insertion member 111 is inserted into the insertion hole 121 as described above, the first housing 110 and the second housing 120 may be securely connected. In addition, because the insertion member 111 is fixed by the locking member 124, the first housing 110 and the second housing 120 may be securely connected.

For example, when an external force is applied to the locking adjustment device 126 and pulls the locking adjustment device 126 in the unlocking direction, the locking member 124 connected to the locking adjustment device 126 may be inserted into the guide hole 122 while compressing the elastic member 123.

The insertion member 111 is inserted into the insertion hole 121 in the state in which the locking member 124 is completely inserted into the guide hole 122. When the external force applied to the locking adjustment device 126 is eliminated in the state in which the insertion member 111 is inserted into the insertion hole 121, the compressed elastic member 123 may be extended and push the locking member 124 toward the insertion member 111.

The locking member 124 is pushed toward the insertion member 111 by the elastic member 123, and the other end of the locking member 124 is inserted into the insertion groove 111a. Therefore, the movement of the insertion member 111 may be restricted.

In this case, the insertion member 111 is inserted after the locking member 124 is removed from the guide hole 122 by the locking adjustment device 126. However, even though the locking member 124 is not separately removed from the guide hole 122 by the locking adjustment device 126, the insertion member 111 may be inserted while pushing the locking member 124 into the guide hole.

For example, as illustrated in the drawings, one surface of the locking member 124 may be inclined. In this case, the defined inclination may allow the locking member 124 to be pushed into the guide hole 122 by the insertion of the insertion member 111.

On the contrary, when an external force is applied to the locking adjustment device 126 and moves the locking adjustment device 126 in the unlocking direction, and the locking member 124 connected to the locking adjustment device 126 may be inserted into the guide hole 122 while pressing the elastic member 123.

When the locking member 124 is inserted into the guide hole 122, the locked state of the other end of the locking member 124, which is inserted into the insertion groove 111a of the insertion member 111, may be released. Therefore, the state in which the insertion member 111 is movable may be implemented.

When the first housing 110 is pulled in a disconnection direction, the insertion member 111 inserted into the insertion hole 121 is separated, such that the first housing 110 and the second housing 120 may be separated.

The first embodiment has been described in which the insertion member 111 is provided on the first housing 110, and the insertion hole 121 is provided in the second housing 120. However, the present invention is not necessarily limited thereto. In case that the insertion member 111 is provided on any one of the first housing 110 and the second housing 120, the insertion hole 121, into which the insertion member 111 is inserted, may be provided in the other housing.

As described above, in the first embodiment of the present invention, the first housing 110 and the second housing 120 may be securely connected by the connection structure in which the insertion members 111 are inserted into the insertion holes 121 and the insertion members 111 are fixed by the locking members 124.

The embodiment has been described in which the guide hole 122 is formed in the y-axis direction. However, the guide hole 122 may be provided in the insertion hole 121 and formed upward or downward in a z-axis direction. In this case, the locking adjustment device 126 may be provided on a lateral surface of the second housing 120.

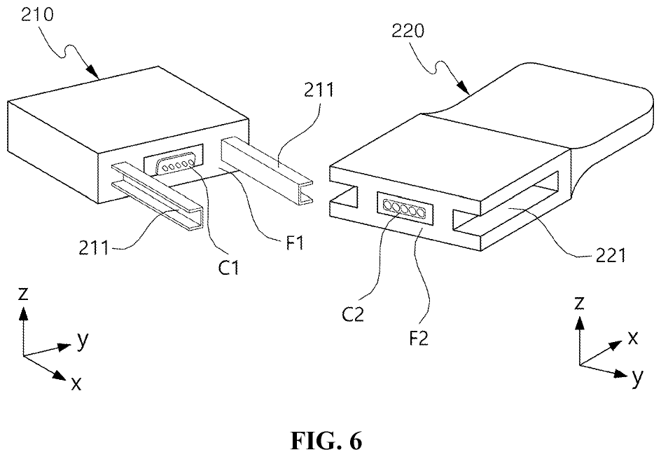

FIG. 6 is an exploded perspective view illustrating a first housing and a second housing according to a second embodiment of the present invention.

As illustrated in FIG. 6, in the second embodiment of the present invention, a first housing 210 and a second housing 220 may be connected by a second connection mechanism.

The second connection mechanism may include insertion members 211 and insertion grooves 221 into which the insertion members 211 are inserted.

The first housing 210 and the second housing 220 may be connected in a state in which the first housing 210 and the second housing 220 are disposed side by side horizontally in a longitudinal direction (e.g., the x-axis direction).

The insertion member 211 may be configured at a position corresponding to the insertion groove 221. The insertion members 211 may be provided at both sides of the first opposing surface F1 of the first housing 210 with the first connector C1 interposed therebetween.

In the second embodiment, one side insertion member 211 between the insertion members 211 provided at the two opposite sides may be positioned between the first connector C1 and one side edge of the first opposing surface F1. The other side insertion member 211 between the insertion members 211 provided at the two opposite sides may be positioned between the first connector C1 and the other side edge of the first opposing surface F1.

The insertion member 211 may have various shapes, such as a “└” or “⊏” shape, that conform to the insertion groove 221.

The insertion grooves 221 may be formed in two opposite surfaces of the second housing 220 and provided in a longitudinal direction (e.g., the x-axis direction) so as to conform to the insertion members 211.

The insertion groove 221 may have various shapes, such as a “└” or “⊏” shape, that conform to the insertion member 211.

The second embodiment has been described in which the insertion member 211 is provided on the first housing 210, and the insertion groove 221 is provided in the second housing 220. However, the present invention is not necessarily limited thereto. In case that the insertion member 211 is provided on any one of the first housing 210 and the second housing 220, the insertion groove 221, into which the insertion member 211 is inserted, may be provided in the other housing.

As described above, in the second embodiment of the present invention, the first housing 210 and the second housing 220 may be securely connected by the connection structure in which the insertion members 211 are inserted into the insertion grooves 221.

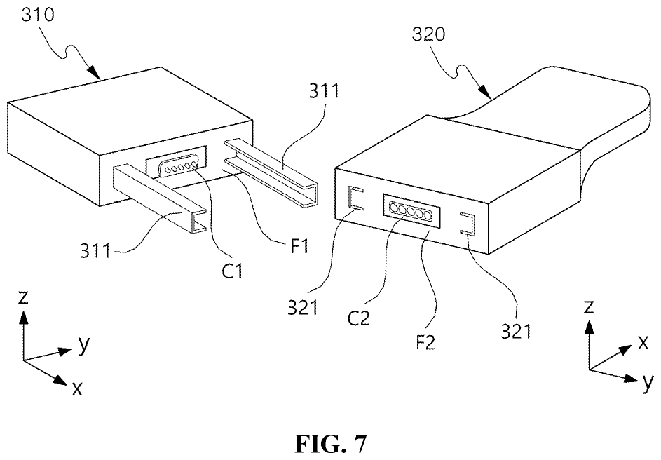

FIG. 7 is an exploded perspective view illustrating a first housing and a second housing according to a third embodiment of the present invention.

As illustrated in FIG. 7, in the third embodiment of the present invention, a first housing 310 and a second housing 320 may be connected by a third connection mechanism.

The third connection mechanism may include insertion members 311 and insertion grooves 321 into which the insertion members 311 are inserted.

The first housing 310 and the second housing 320 may be connected in a state in which the first housing 310 and the second housing 320 are disposed side by side horizontally in a longitudinal direction (e.g., the x-axis direction).

The insertion member 311 is formed at a position corresponding to the insertion groove 321. The insertion members 311 are formed at two opposite sides of the first opposing surface F1 of the first housing 310 with the first connector C1 interposed therebetween. The insertion member 311 may be formed in the x-axis direction.

The insertion member 311 protrudes toward the second opposing surface F2 of the second housing 320. The insertion member 311 may have various shapes, such as a “└” or “⊏” shape, that conform to the insertion groove 321.

The insertion grooves 321 are formed at two opposite sides of the second opposing surface F2 of the second housing 320 with the second connector C2 interposed therebetween. The insertion member 311 is inserted into the insertion groove 321. The insertion groove 321 may have various shapes, such as a “└” or “⊏” shape, that conform to the insertion member 311.

The third embodiment has been described in which the insertion member 311 is provided on the first housing 310, and the insertion groove 321 is provided in the second housing 320. However, the present invention is not necessarily limited thereto. In case that the insertion member 311 is provided on any one of the first housing 310 and the second housing 320, the insertion groove 321, into which the insertion member 311 is inserted, may be provided in the other housing.

As described above, in the third embodiment of the present invention, the first housing 310 and the second housing 320 may be securely connected by the connection structure in which the insertion members 311 are inserted into the insertion grooves 321.

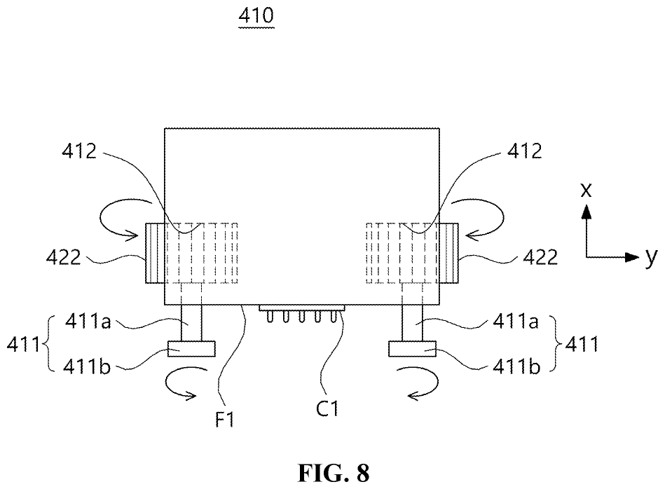

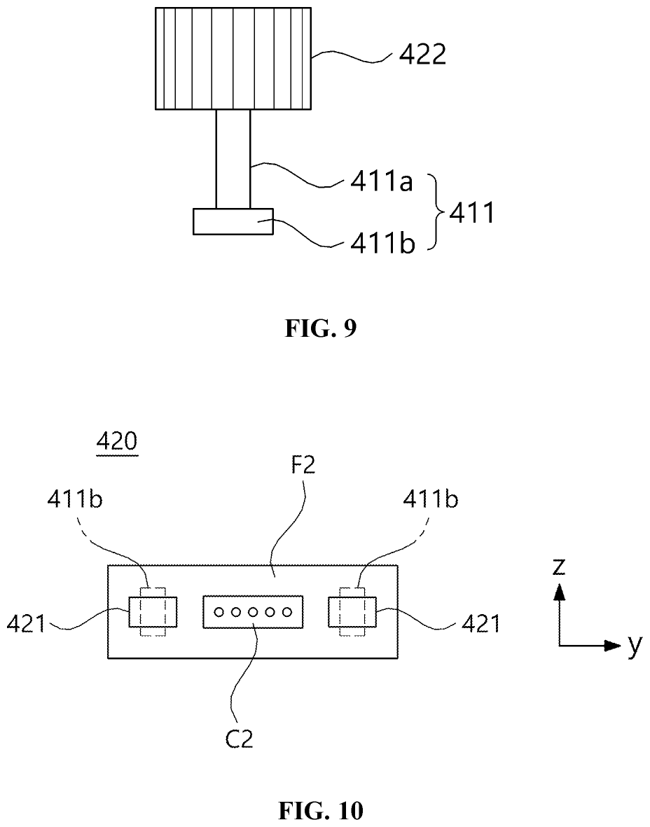

FIG. 8 is a top plan view illustrating a first housing according to a fourth embodiment of the present invention, FIG. 9 is an enlarged view illustrating an insertion member according to the fourth embodiment of the present invention, and FIG. 10 is a front view illustrating a second housing according to the fourth embodiment of the present invention.

As illustrated in FIGS. 8 to 10, in the fourth embodiment of the present invention, a first housing 410 and a second housing 420 may be connected by a fourth connection mechanism.

The fourth connection mechanism may include insertion members 411, insertion grooves 421 into which the insertion members 411 are inserted, and locking adjustment devices 422 configured to rotate the insertion members 411.

The first housing 410 and the second housing 420 may be connected in a state in which the first housing 410 and the second housing 420 are disposed side by side horizontally in a longitudinal direction (e.g., the x-axis direction).

The insertion member 411 may be formed in a shape such as a “T” shape. The insertion member 411 may include an extension portion 411a and a locking member 411b.

The extension portions 411a may be provided at two opposite sides of the first opposing surface F1 of the first housing 410 with the first connector C1 interposed therebetween.

The locking member 411b may be provided at an end of the extension portion 411a. The locking member 411b may be connected to the extension portion 411a and formed in a direction intersecting the extension portion 411a. For example, the extension portion 411a may be formed in the x-axis direction. In a state in which the locking members 411b are provided at the ends of the extension portions 411a and aligned in the y-axis direction, the locking members 411b may be inserted into the insertion grooves 421 and rotated in the z-axis direction.

The insertion grooves 421 are provided at two opposite sides of the second opposing surface F2 of the second housing 420. The insertion member 411 is inserted into the insertion groove 421.

The locking adjustment device 422 is connected to the extension portion 411a. The insertion member 411 may be inserted into an accommodation portion 412 of the first housing 410, and at least a part of the insertion member 411 may be exposed to the outside of the accommodation portion 412.

When the locking adjustment device 422 is rotated in a locking direction in the state in which the insertion member 411 is inserted into the insertion groove 421, the locking member 411b may be rotated in the direction intersecting the insertion groove 421 and caught by the insertion groove 421.

Specifically, the insertion member 411 may be inserted into the insertion groove 421 in the state in which the insertion member 411 is aligned in the y-axis direction, and the insertion member 411 may be locked when the insertion member 411 is rotated in the z-axis direction after being inserted.

The fourth embodiment has been described in which the insertion member 411 is provided on the first housing 410, and the insertion groove 421 is provided in the second housing 420. However, the present invention is not necessarily limited thereto. In case that the insertion member 411 is provided on any one of the first housing 410 and the second housing 420, the insertion groove 421, into which the insertion member 411 is inserted, may be provided in the other housing.

As described above, in the fourth embodiment of the present invention, the first housing 410 and the second housing 420 may be securely connected by the connection structure that implements a locked state in which the locking member 411b is caught while intersecting the insertion groove 421 of the second housing 420 when the locking adjustment device 422 rotates in the state in which the insertion member 411 is inserted into the insertion groove 421.

On the contrary, when the locking adjustment device 422 rotates in an unlocking direction, the locking member 411b, which intersects the insertion groove 421, is consistent with the insertion groove 421, such that the locking member 411b may be withdrawn through the insertion groove 421.

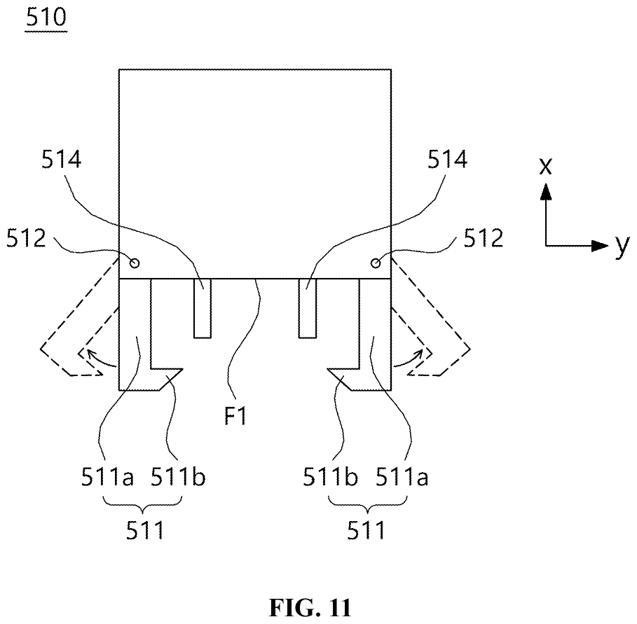

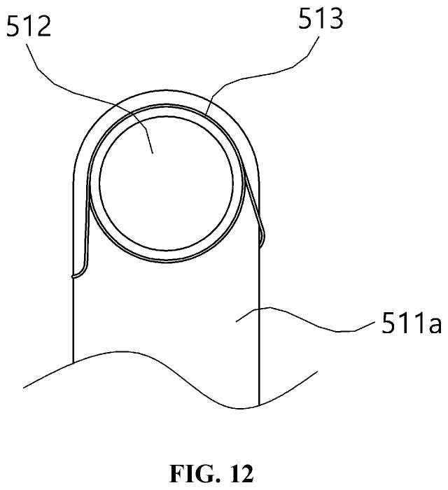

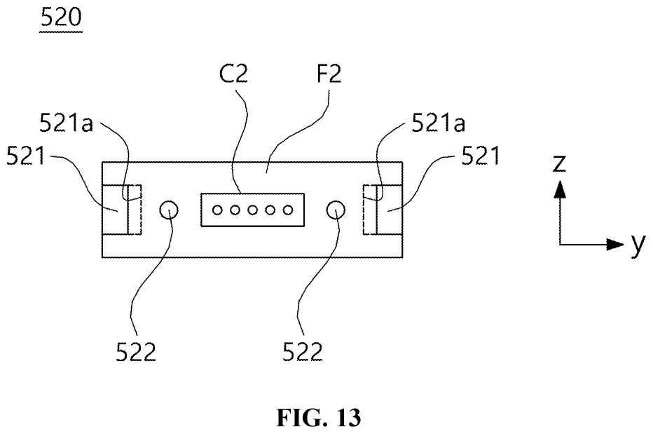

FIG. 11 is a top plan view illustrating a first housing according to a fifth embodiment of the present invention, FIG. 12 is a view illustrating an elastic member coupled to a hinge shaft according to the fifth embodiment of the present invention, and FIG. 13 is a front view illustrating a second housing according to the fifth embodiment of the present invention.

As illustrated in FIGS. 11 to 13, in the fifth embodiment of the present invention, a first housing 510 and a second housing 520 may be connected by a fifth connection mechanism.

The fifth connection mechanism may include locking members 511, insertion grooves 521 into which the locking members 511 are inserted, insertion members 514, and insertion holes 522 into which the insertion members 514 are inserted.

The first housing 510 and the second housing 520 may be connected in a state in which the first housing 510 and the second housing 520 are disposed side by side horizontally in a longitudinal direction.

The locking members 511 may be provided at two opposite sides of the first opposing surface F1 of the first housing 510. One end of the locking member 511 is connected to the first housing 510 by a hinge shaft 512. The locking member 511 may rotate about the hinge shaft 512.

The locking member 511 may include an extension portion 511a and a catching projection 511b. One end of the extension portion 511a may be connected to the first housing 510 by the hinge shaft 512. The extension portion 511a is elastically supported by an elastic member 513 coupled to the hinge shaft 512. The locking member 511 may be securely inserted into the insertion groove 521 by an elastic force of the elastic member 513.

For example, the elastic member 513 may be a torsion spring. The catching projection 511b may be provided at the other end of the extension portion 511a.

The insertion grooves 521 are formed in two opposite surfaces of the second housing 520 and provided in the longitudinal direction. The extension portion 511a is inserted into the insertion groove 521. The catching projection 511b may be inserted into a catching groove 521a provided in the insertion groove 521.

The insertion member 514 may be formed in the x-axis direction. The insertion members 514 may be provided at two opposite sides of the first opposing surface F1 of the first housing 510. The insertion members 514 may be provided between the locking members 511 disposed at the two opposite sides. The insertion members 514 may protrude from the two opposite sides of the first opposing surface F1 of the first housing 510 toward the second opposing surface F2 of the second housing 520.

The insertion holes 522 are provided at two opposite sides of the second opposing surface F2 of the second housing 520 with the second connector C2 interposed therebetween. The insertion holes 522 may be provided between the insertion grooves 521 disposed at the two opposite sides. The insertion member 514 may be inserted into the insertion hole 522.

The fifth embodiment has been described in which the insertion member 514 is provided on the first housing 510, and the insertion hole 522 is provided in the second housing 520. However, the present invention is not necessarily limited thereto. In case that the insertion member 514 is provided on any one of the first housing 510 and the second housing 520, the insertion hole 522, into which the insertion member 514 is inserted, may be provided in the other housing.

As described above, in the fifth embodiment of the present invention, the first housing 510 and the second housing 520 may be securely connected by the connection structure in which the locking members 511 are inserted into the insertion grooves 521 and the insertion members 514 are inserted into the insertion holes 522.

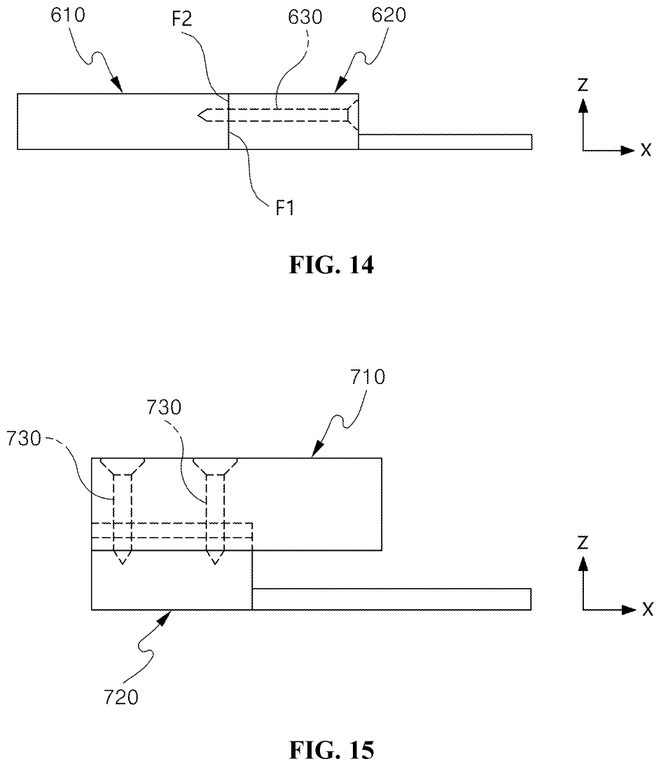

FIG. 14 is a side view illustrating a state in which a first housing and a second housing according to a sixth embodiment of the present invention are connected horizontally.

As illustrated in FIG. 14, in the sixth embodiment of the present invention, a first housing 610 and a second housing 620 may be connected by a sixth connection mechanism. The sixth connection mechanism may include a connection member 630.

The first housing 610 and the second housing 620 may be connected by the connection member 630 in a state in which the first housing 610 and the second housing 620 are disposed side by side in the x-axis direction.

In a state in which the first housing 610 and the second housing 620 are arranged horizontally, the connection member 630 is coupled horizontally while penetrating the first housing 610 and the second housing 620. The connection member 630 may be coupled in the x-axis direction.

For example, the connection member 630 may be a bolt screw-coupled while penetrating the first housing 610 and the second housing 620.

As described above, in the sixth embodiment of the present invention, the first housing 610 and the second housing 620 may be securely connected by the connection structure such as the connection member 630 screw-coupled while penetrating the first housing 610 and the second housing 620.

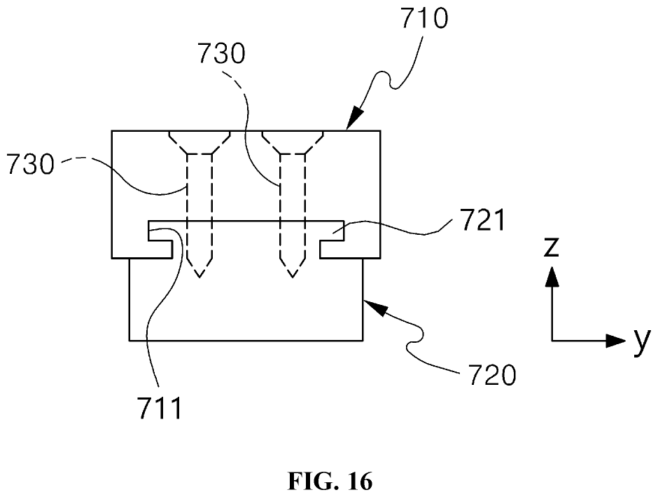

FIG. 15 is a side view illustrating a state in which a first housing and a second housing according to a seventh embodiment of the present invention are connected vertically, and FIG. 16 is a front view illustrating the state in which the first housing and the second housing according to the seventh embodiment of the present invention are connected vertically.

As illustrated in FIGS. 15 and 16, in the seventh embodiment of the present invention, a first housing 710 and a second housing 720 may be connected by a seventh connection mechanism. As illustrated in FIGS. 15 and 16, the seventh connection mechanism may include connection members 730 configured to connect the first housing 710 and the second housing 720. In the seventh embodiment, the first housing 710 and the second housing 720 may be fixed only by the connection members 730. However, additionally, a sliding structure may be further included, and the sliding structure may include a sliding groove 711 provided in the first housing 710, and a sliding rail 721 of the second housing 720 that is inserted into the sliding groove 711.

The sliding groove 711 is provided in a lower portion of the first housing 710. The sliding rail 721 is formed on an upper portion of the second housing 720. The sliding rail 721 may be formed to conform to the sliding groove 711 so that the sliding rail 721 may be slidably inserted into the sliding groove 711.

In the state in which the first housing 710 and the second housing 720 are connected vertically in the z-axis direction in which the sliding rail 721 is inserted into the sliding groove 711, the connection members 730 are coupled while penetrating the first housing 710 and the second housing 720. For example, the connection member 730 may be coupled vertically in the z-axis direction.

For example, the connection member 730 may be a bolt screw-coupled while penetrating the first housing 710 and the second housing 720.

As described above, in the seventh embodiment of the present invention, the first housing 710 and the second housing 720 may be securely connected by the connection structure in which the connection members 730 are screw-coupled while vertically penetrating the first housing 710 and the second housing 720 in the state in which the sliding rail 721 of the second housing 720 is slidably inserted into the sliding groove 711 of the first housing 710.

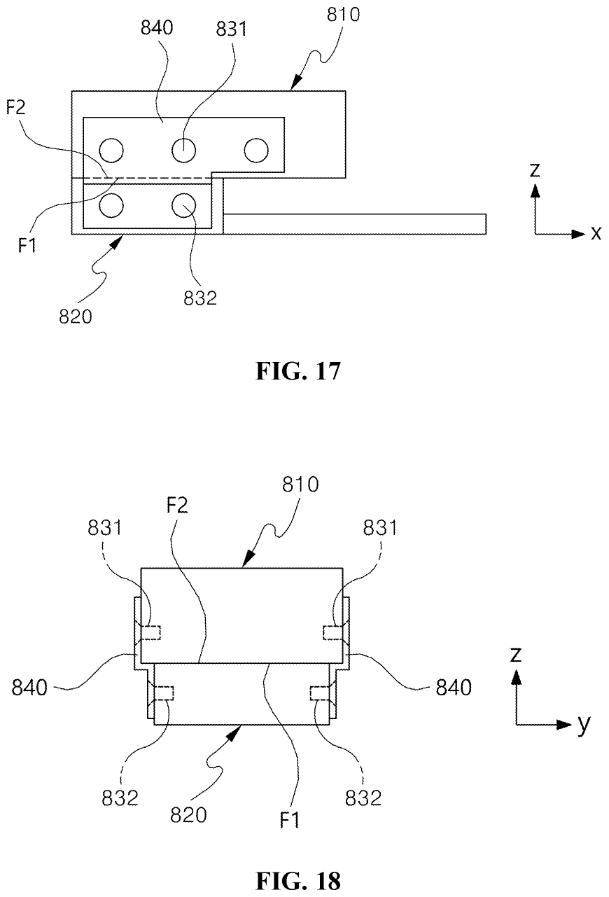

FIG. 17 is a side view illustrating a state in which a first housing and a second housing according to an eighth embodiment of the present invention are connected vertically, and FIG. 18 is a front view illustrating the state in which the first housing and the second housing according to the eighth embodiment of the present invention are connected vertically.

As illustrated in FIGS. 17 and 18, in the eighth embodiment of the present invention, a first housing 810 and a second housing 820 may be connected by an eighth connection mechanism.

The eighth connection mechanism may include connection plates 840, first connection members 831 coupled while penetrating the connection plates 840, and second connection members 832 connected while penetrating the connection plates 840.

The first housing 810 and the second housing 820 may be disposed in the z-axis direction. In a state in which the first housing 810 and the second housing 820 are arranged vertically, the connection plates 840, which connect the first housing 810 and the second housing 820, are attached to two opposite sides of the first housing 810 and two opposite sides of the second housing 820.

For example, the first connection member 831 and the second connection member 832 may be bolts screw-coupled to the first housing 810 and the second housing 820 while penetrating the connection plates 840. The first connection member 831 and the second connection member 832 may be coupled in the y-axis direction.

As described above, in the eighth embodiment of the present invention, the first housing 810 and the second housing 820 may be securely connected by the connection structure in which the first connection members 831 and the second connection members 832 are screw-coupled to the first housing 810 and the second housing 820 while penetrating the connection plates 840 in the state in which the first housing 810 and the second housing 820 are disposed vertically and the connection plates 840 are attached to the two opposite sides of the first housing 810 and the two opposite sides of the second housing 820.

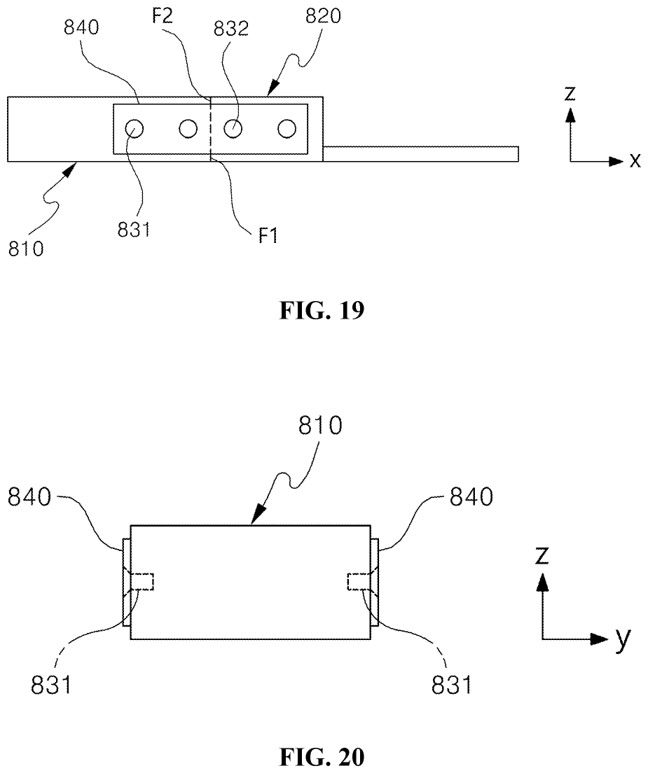

FIG. 19 is a side view illustrating a state in which the first housing and the second housing according to another embodiment of FIG. 18 are connected horizontally, and FIG. 20 is a front view illustrating the state in which the first housing and the second housing according to the eighth embodiment of the present invention are connected horizontally.

As illustrated in FIGS. 19 and 20, the first housing 810 and the second housing 820 are disposed side by side in the x-axis direction. In a state in which the first housing 810 and the second housing 820 are arranged horizontally, the connection plates 840, which connect the first housing 810 and the second housing 820, are attached to two opposite sides of the first housing 810 and two opposite sides of the second housing 820.

The first connection member 831 may be coupled to the first housing 810 while penetrating the connection plate 840, and the second connection member 832 may be coupled to the second housing 820 while penetrating the connection plate 840.

The first connection member 831 and the second connection member 832 may be coupled in the y-axis direction.

For example, the first connection member 831 and the second connection member 832 may be bolts screw-coupled to the first housing 810 and the second housing 820 while penetrating the connection plates 840.

As described above, in the eighth embodiment of the present invention, the first housing 810 and the second housing 820 may be securely connected by the connection structure in which the first connection members 831 and the second connection members 832 are screw-coupled to the first housing 810 and the second housing 820 while penetrating the connection plates 840 in the state in which the first housing 810 and the second housing 820 are disposed horizontally and the connection plates 840 are attached to the two opposite sides of the first housing 810 and the two opposite sides of the second housing 820.

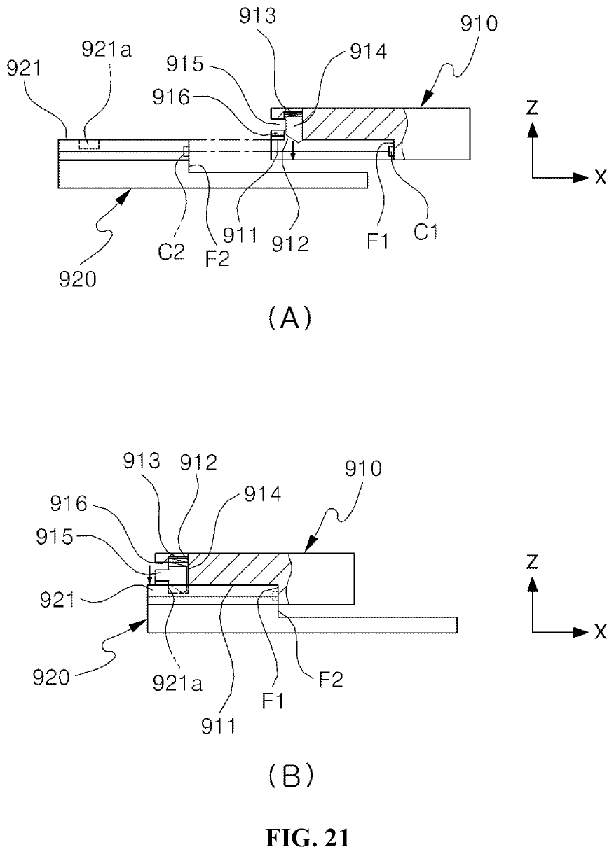

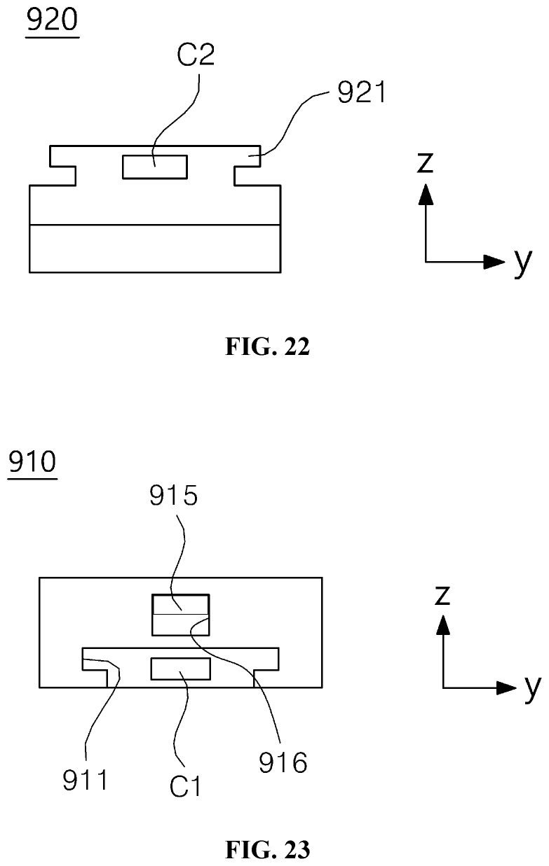

FIG. 21 is a view illustrating a process of connecting a first housing and a second housing according to a ninth embodiment of the present invention, FIG. 22 is a front view illustrating the second housing according to the ninth embodiment of the present invention, and FIG. 23 is a front view illustrating the first housing according to the ninth embodiment of the present invention.

As illustrated in FIGS. 21 to 23, in the ninth embodiment of the present invention, a first housing 910 and a second housing 920 may be connected by a ninth connection mechanism.

The ninth connection mechanism may include a sliding groove 911, a sliding rail 921 slidably coupled to the sliding groove 911, a guide hole 912 provided in the first housing 910, a locking member 914 coupled to the guide hole 912, and a locking adjustment device 915 configured to move the locking member 914.

The sliding rail 921 formed on an upper portion of the second housing 920 may be slidably coupled, in the x-axis direction, to the sliding groove 911 formed in a lower portion of the first housing 910. An insertion groove 921a may be provided in an upper surface of the sliding rail 921 of the second housing 920.

The first opposing surface F1 is provided on an inner surface of the sliding groove 911 of the first housing 910. The first opposing surface F2 is provided on one surface of the second housing 920 directed toward the first opposing surface F1. The first opposing surface F1 and the second opposing surface F2 are formed in the x-axis direction. The first connector C1 may be provided on the first opposing surface F1, and the second connector C2 may be provided on the second opposing surface F2.

The guide hole 912 is formed in the z-axis direction. The guide hole 912 may be formed in a direction intersecting the sliding groove 911 and provided in the first housing 910 so as to communicate with the sliding groove 911.

One end of the locking member 914, which is inserted into the guide hole 912, may be elastically supported by an elastic member 913, and the other end of the locking member 914, which is directed toward the second housing 920, may be inserted into the insertion groove 921a. For example, the elastic member 913 may be a coiled spring.

The locking adjustment device 915 may be connected to the locking member 914 and move the locking member 914 in a locking direction. The locking adjustment device 915 may move along an operating space 916 provided in the first housing 910. For example, the locking adjustment device 915 may be a lever, a switch, a button, or the like.

When the sliding rail 921 of the second housing 920 is inserted into the sliding groove 911 of the first housing 910, the first connector C1 of the first housing 910 and the second connector C2 of the second housing 920 may be connected.

When an external force is applied to the locking adjustment device 915 and pushes the locking adjustment device 915 in an unlocking direction, the locking member 914 connected to the locking adjustment device 915 may be inserted into the guide hole 912 while compressing the elastic member 913. In a state in which the locking member 914 is completely inserted into the guide hole 912, the sliding rail 921 is slidably inserted into the sliding groove 911 in the x-axis direction.

When the external force, which is applied to the locking adjustment device 915, is eliminated in the state in which the sliding rail 921 is inserted into the sliding groove 911, the locking member 914 connected to the locking adjustment device 915 may move in the locking direction, and the other end of the locking member 914 may be inserted into the insertion groove 921a.

As described above, in the ninth embodiment of the present invention, the first housing 910 and the second housing 920 may be securely connected by the connection structure in which the sliding rail 921 is slidably inserted into the sliding groove 911 and the locking member 914 is inserted into the insertion groove 921a.

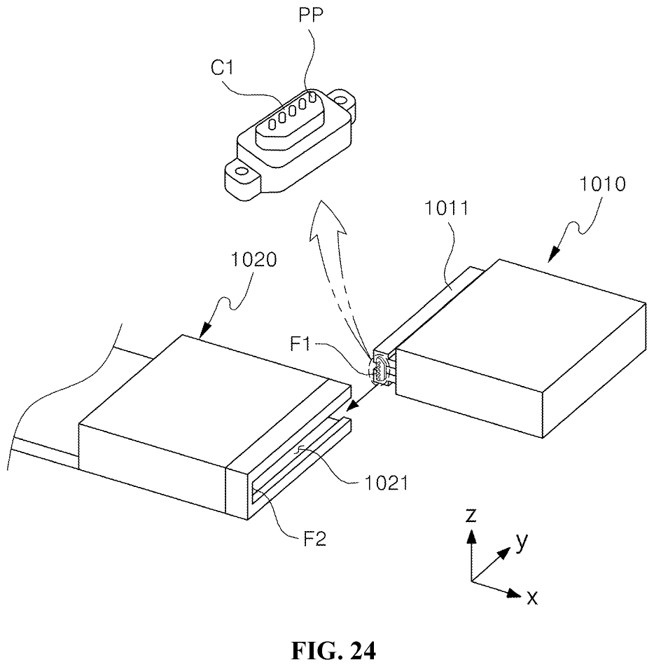

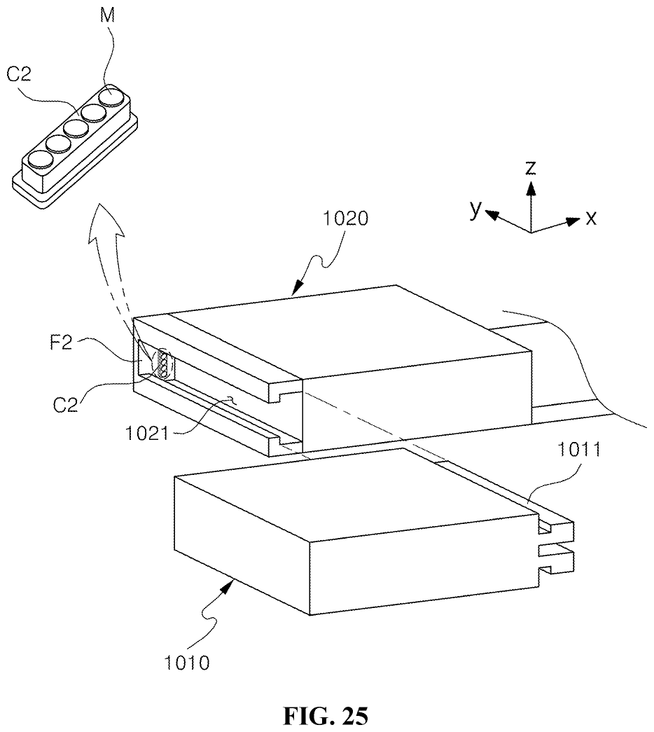

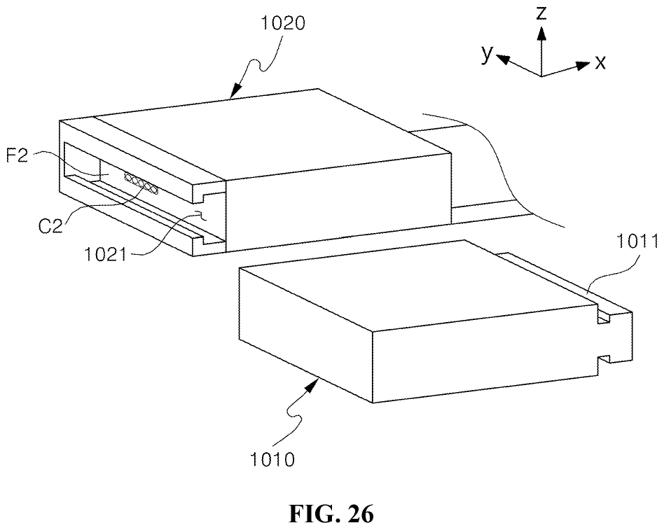

FIG. 24 is an exploded perspective view illustrating a first housing and a second housing according to a tenth embodiment of the present invention when viewed from the second housing, and FIG. 25 is an exploded perspective view illustrating the first housing and the second housing according to the tenth embodiment of the present invention when viewed from the first housing.

As illustrated in FIGS. 24 to 25, in the tenth embodiment of the present invention, a first housing 1010 and a second housing 1020 may be connected by a tenth connection mechanism.

The tenth connection mechanism may include a sliding rail 1011 provided on the first housing 1010, and a sliding groove 1021 provided in the second housing 1020.

The sliding rail 1011 is provided on one surface of the first housing 1010 based on a longitudinal direction (e.g., the x-axis direction) and formed in a direction (e.g., the y-axis direction) intersecting the longitudinal direction of the first housing 1010. The first opposing surface F1 may be provided on a surface that enters the sliding groove 1021 of the sliding rail 1011.

The first connector C1 is provided on the first opposing surface F1. The first connector C1 is formed in the direction (e.g., the y-axis direction) intersecting the longitudinal direction (e.g., the x-axis direction) of the first housing 1010. For example, the first connector C1 may be a connector having a pogo pin PP.

The sliding groove 1021 is provided on one surface of the second housing 1020 based on the longitudinal direction (e.g., the x-axis direction) and formed in the direction (e.g., the y-axis direction) intersecting the longitudinal direction of the second housing 1020. The second opposing surface F2 may be provided on an inner end surface of the sliding groove 1021 and correspond to the first opposing surface F1.

The second connector C2 connected to the first connector C1 may be provided on the second opposing surface F2. The second connector C2 is formed in the direction (e.g., the y-axis direction) intersecting the longitudinal direction (e.g., the x-axis direction) of the second housing 1020. For example, the second connector C2 may be a magnetic connector having a magnetic M to which the pogo pin PP of the first connector C1 may be connected.

As described above, when the sliding rail 1011 is inserted into the sliding groove 1021 in a state in which the sliding rail 1011 of the first housing 1010 is consistent with the sliding groove 1021 of the second housing 1020, the first connector C1, which is formed in the direction (e.g., the y-axis direction) intersecting the longitudinal direction (e.g., the x-axis direction) of the first housing 1010, may be connected to the second connector C2 formed in the direction (e.g., the y-axis direction) intersecting the longitudinal direction (e.g., the x-axis direction) of the second housing 1020. The first housing 1010 and the second housing 1020 may be securely connected by the connection structure.

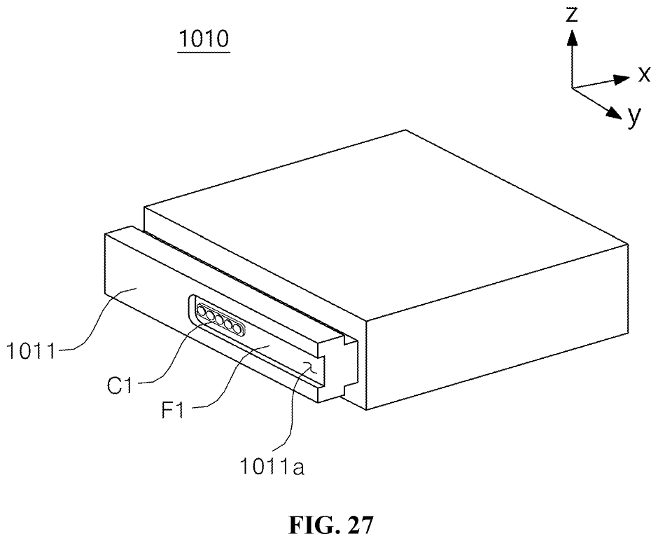

FIG. 26 is a perspective view illustrating a second opposing surface of the second housing according to the tenth embodiment of the present invention, and FIG. 27 is a view illustrating a first opposing surface of the first housing according to the tenth embodiment of the present invention.

As illustrated in FIGS. 26 and 27, the sliding rail 1011 is provided on one surface of the first housing 1010 based on the longitudinal direction (e.g., the x-axis direction) and formed in the intersecting direction (e.g., the y-axis direction), and an accommodation groove 1011a is provided in the longitudinal direction (e.g., the y-axis direction) of the sliding rail 1011. The first opposing surface F1 may be provided in the accommodation groove 1011a.

The first connector C1 is provided on the first opposing surface F1. The first connector C1 may be positioned at an inner end of the accommodation groove 1011a so as to correspond to the second connector C2.

The first connector C1 is formed in the direction (e.g., the x-axis direction) identical to the longitudinal direction (e.g., the x-axis direction) of the first housing 1010. For example, the first connector C1 may be a connector having a pogo pin PP.

The sliding groove 1021 is provided on one surface of the second housing 1020 based on the longitudinal direction (e.g., the x-axis direction) and formed in the intersecting direction (e.g., the y-axis direction). The second opposing surface F2 may be provided at a position corresponding to the first opposing surface F1 of the sliding groove 1021.

The second connector C2 connected to the first connector C1 is provided on the second opposing surface F2.

The second connector C2 is formed in the direction (e.g., the x-axis direction) identical to the longitudinal direction (e.g., the x-axis direction) of the second housing 1020. For example, the second connector C2 may be a magnetic connector having a magnetic M to which the pogo pin PP of the first connector C1 may be connected.

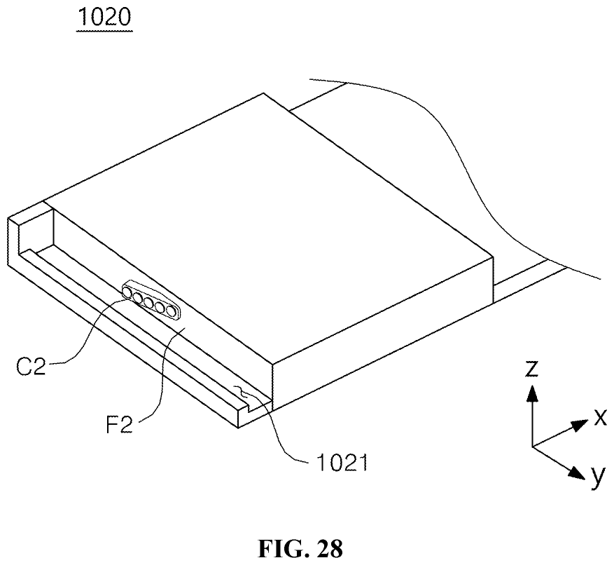

As illustrated in FIGS. 24 to 27, the first connector C1 and the second connector C2 may each be configured as a horizontal connector. Alternatively, as illustrated in FIG. 28, the first connector C1 and the second connector C2 may each be configured as an inclined connector.

As described above, when the sliding rail 1011 is inserted into the sliding groove 1021 in a state in which the sliding rail 1011 of the first housing 1010 is consistent with the sliding groove 1021 of the second housing 1020, the first connector C1, which is formed in the direction (e.g., the x-axis direction) identical to the longitudinal direction (e.g., the x-axis direction) of the first housing 1010, may be connected to the second connector C2 formed in the direction (e.g., the x-axis direction) identical to the longitudinal direction (e.g., the x-axis direction) of the second housing 1020. The first housing 1010 and the second housing 1020 may be securely connected by the connection structure.

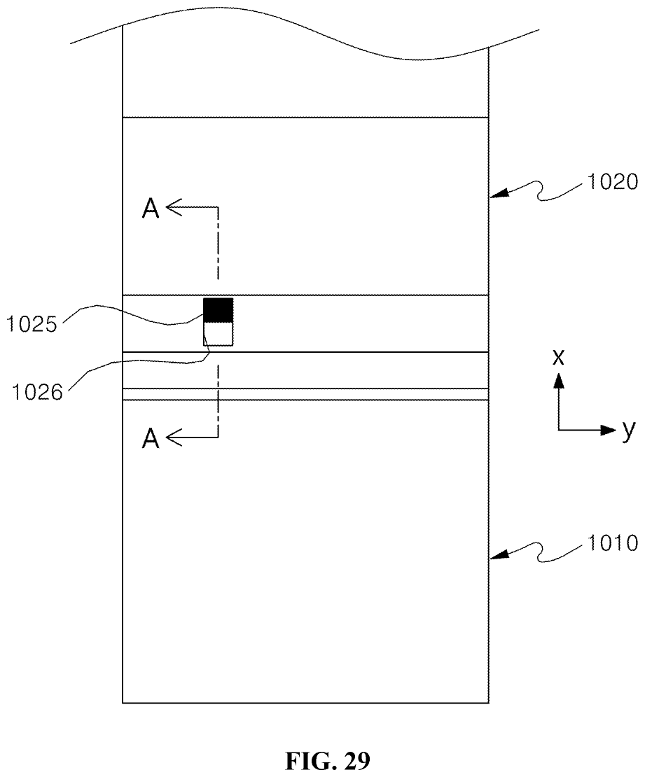

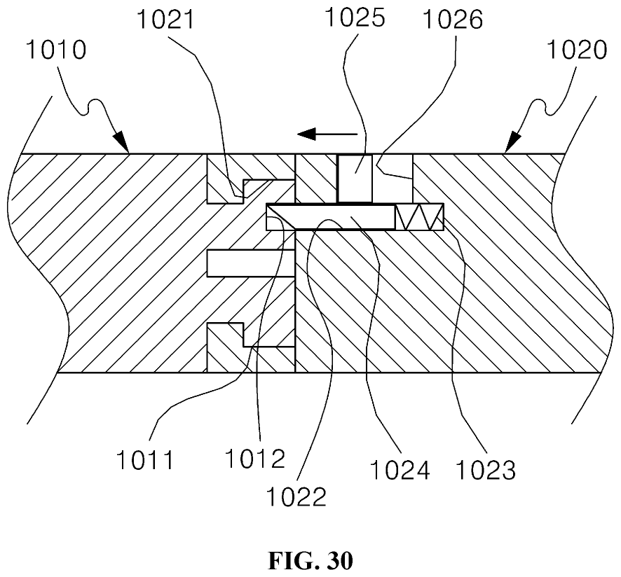

FIG. 29 is a top plan view illustrating a state in which the first housing and the second housing according to the tenth embodiment of the present invention are connected, and FIG. 30 is a cross-sectional view taken along line A-A in FIG. 29.

As illustrated in FIGS. 29 and 30, the tenth connection mechanism may include a guide hole 1022 provided in the second housing 1020, a locking member 1024 inserted into the guide hole 1022, and a locking adjustment device 1025 connected to the locking member 1024.

The guide hole 1022 is provided in the second housing 1020 and formed in the direction (e.g., the x-axis direction) intersecting the sliding groove 1021. The guide hole 1022 may be configured to communicate with the sliding groove 1021.

One end of the locking member 1024, which is inserted into the guide hole 1022, is elastically supported by an elastic member 1023 provided in the guide hole 1022. For example, the elastic member 1023 may be a coiled spring. The other end of the locking member 1024 may be inserted into an insertion groove 1012 of the first housing 1010.

The locking adjustment device 1025 is connected to the locking member 1024. The locking adjustment device 1025 may move the locking member 1024 in the locking direction while moving along an operating space 1026 provided in the second housing 1020.

As illustrated in FIGS. 24 to 30, when an external force is applied to the locking adjustment device 1025 and moves the locking adjustment device 1025 in the unlocking direction, the locking member 1024 connected to the locking adjustment device 1025 may be inserted into the guide hole 1022 while compressing the elastic member 1023.

When the sliding rail 1011 of the first housing 1010 is slidably inserted into the sliding groove 1021 of the second housing 1020 in the state in which the locking member 1024 is completely inserted into the guide hole 1022, the first connector C1 and the second connector C2 may be connected.

When the external force, which is applied to the locking adjustment device 1025, is eliminated in the state in which the sliding rail 1011 is inserted into the sliding groove 1021, the compressed elastic member 1023 may be extended.

The locking member 1024 may be pushed toward the first housing 1010 by the elastic member 1023, and the other end of the locking member 1024 may be inserted into the insertion groove 1012 of the first housing 1010.

As described above, in the tenth embodiment of the present invention, the first housing 1010 and the second housing 1020 may be securely connected by the connection structure such as the sliding rail 1011, which is inserted into the sliding groove 1021, and the locking member 1024 inserted into the insertion groove 1012.

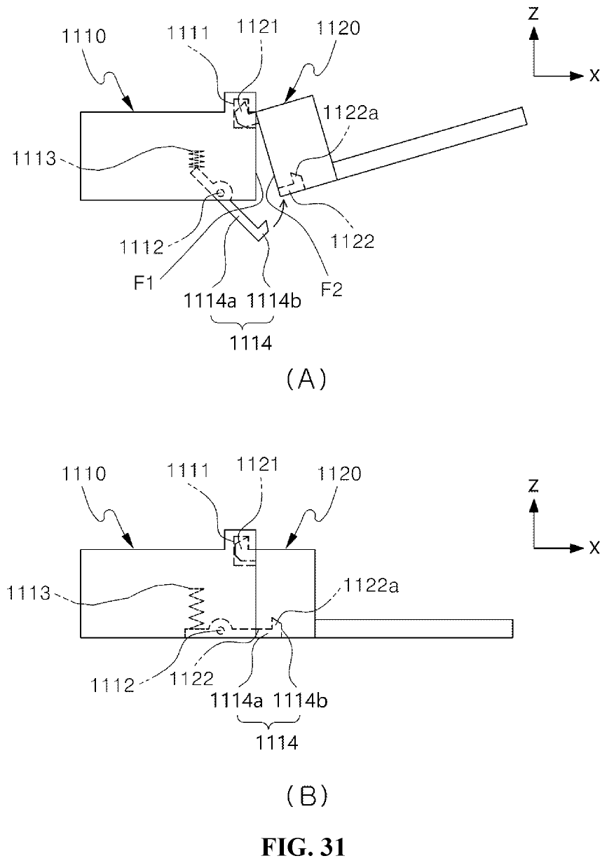

FIG. 31 is a side view illustrating a process of connecting a first housing and a second housing according to an eleventh embodiment of the present invention.

As illustrated in FIG. 31, in the eleventh embodiment of the present invention, a first housing 1110 and a second housing 1120 may be connected by an eleventh connection mechanism.

The eleventh connection mechanism may include a hook 1121, an assembling groove 1111 into which the hook 1121 is inserted, a locking member 1114, and an insertion groove 1122 into which the locking member 1114 is inserted.

The first housing 1110 and the second housing 1120 may be connected in a state in which the first housing 1110 and the second housing 1120 are disposed side by side horizontally in a longitudinal direction (an x-axis direction).

The assembling groove 1111 is provided in an upper portion of the first opposing surface F1 of the first housing 1110. One end of the locking member 1114 may be connected to a lower inner portion of the first housing 1110 by a hinge shaft 1112.

The locking member 1114 may rotate about the hinge shaft 1112. The locking member 1114 may include an extension portion 1114a and a catching projection 1114b.

One end of the extension portion 1114a is provided in the first housing 1110 and elastically supported by an elastic member 1113. For example, the elastic member 1113 may be a coiled spring.

The catching projection 1114b is provided at the other end of the extension portion 1114a. The other end of the extension portion 1114a and the catching projection 1114b may be positioned on a bottom surface of the second housing 1120 by a rotation of the locking member 1114.

At least one hook 1121 may be provided on an upper portion of the second opposing surface F2 of the second housing 1120. For example, the hook 1121 may be provided at two opposite left and right sides of the second housing 1120.

The insertion groove 1122 is formed in the bottom surface of the second housing 1120. The insertion groove 1122 may have a catching groove 1122a.

As illustrated in FIG. 31A, when an external force is applied to the locking member 1114, the locking member 1114 may rotate about the hinge shaft 1112 while compressing the elastic member 1113.

In a state in which the locking member 1114 is rotated about the hinge shaft 1112 and positioned on the bottom surface of the first housing 1110, the hook 1121 of the second housing 1120 may be inserted into the assembling groove 1111 of the first housing 1110.

In case that the hook 1121 is inserted into the assembling groove 1111 in a state in which the locking member 1114 is not positioned on the bottom surface of the first housing 1110, the second housing 1120 is caught by the locking member 1114, and the hook 1121 cannot be inserted into the assembling groove 1111. Therefore, the hook 1121 may be inserted into the assembling groove 1111 in the state in which the locking member 1114 is positioned on the bottom surface of the first housing 1110.

As illustrated in FIG. 31B, in the state in which the hook 1121 is inserted into the assembling groove 1111, the second opposing surface F2 of the second housing 1120 may be in close contact with the first opposing surface F1 of the first housing 1110.

When the external force, which is applied to the locking member 1114, is eliminated, the compressed elastic member 1113 may be extended, and the elastic force of the elastic member 1113 may be applied to the locking member 1114.

The locking member 1114 may be pushed by the elastic member 1113 and rotated about the hinge shaft 1112 to an original state.

As the locking member 1114 rotates to the original state, the other end of the extension portion 1114a may be inserted into the insertion groove 1122 of the second housing 1120, and the catching projection 1114b may be inserted into the catching groove 1122a of the insertion groove 1122.

As described above, in the eleventh embodiment of the present invention, the first housing 1110 and the second housing 1120 may be securely connected by the connection structure in which the hook 1121 is inserted into the assembling groove 1111, and the catching projection 1114b and the other end of the extension portion 1114a of the locking member 1114 are inserted into the insertion groove 1122 and the catching groove 1122a.

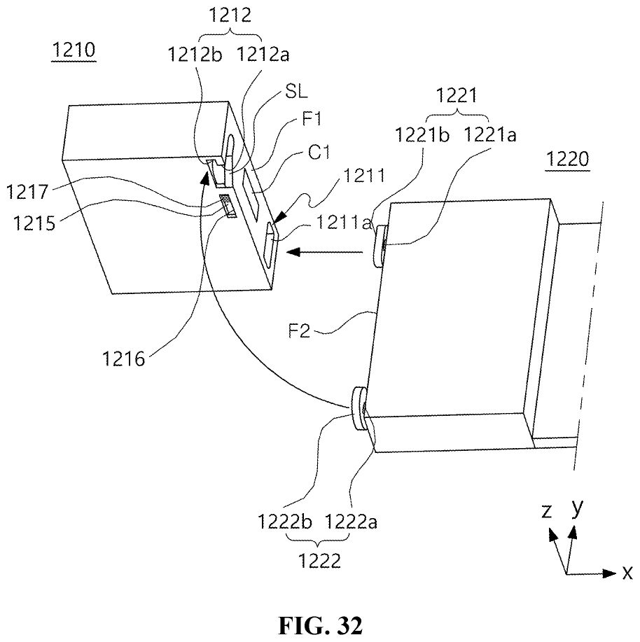

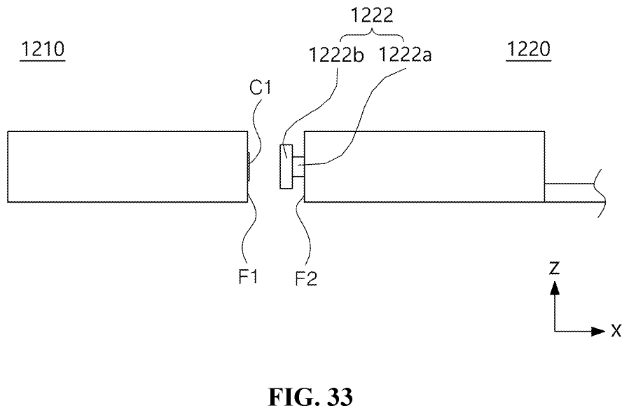

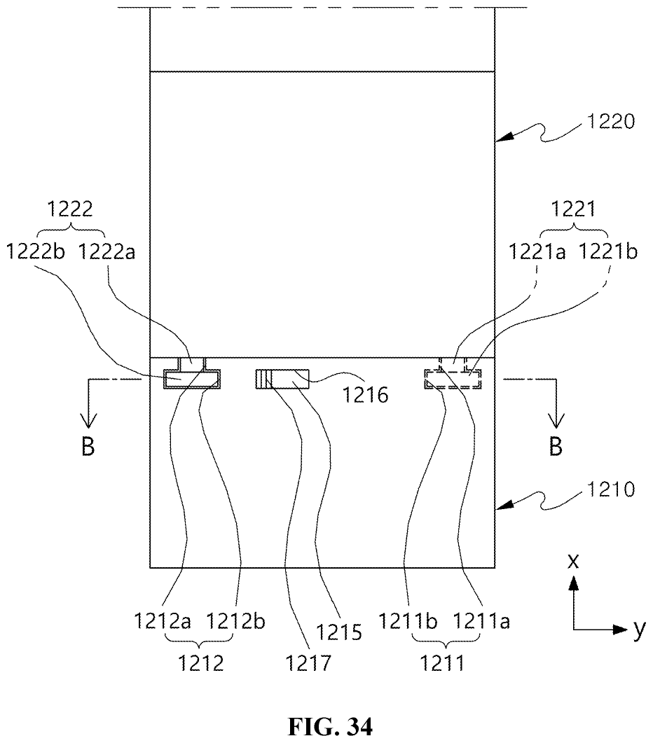

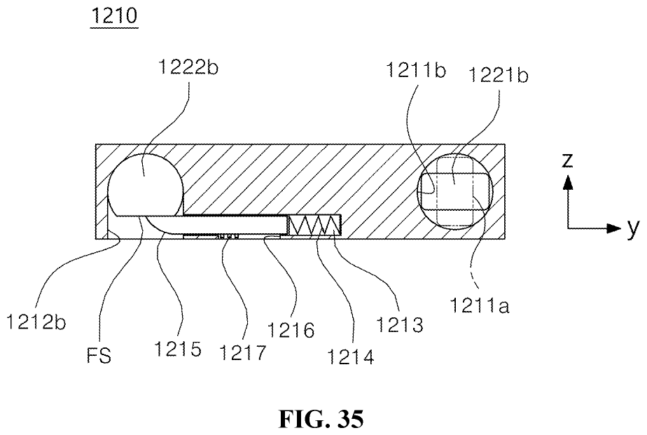

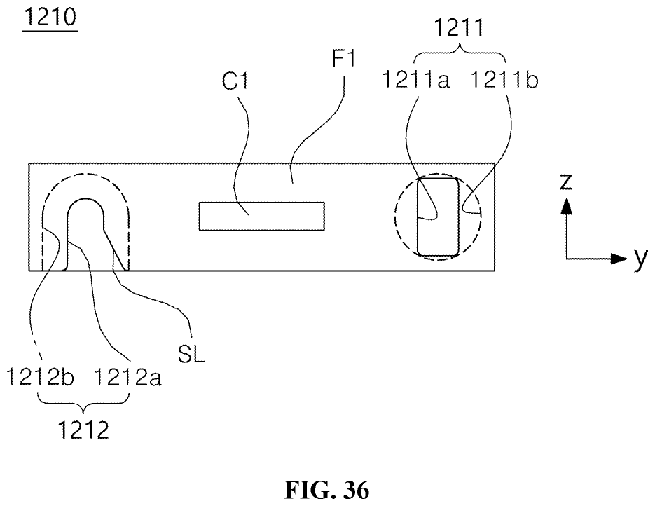

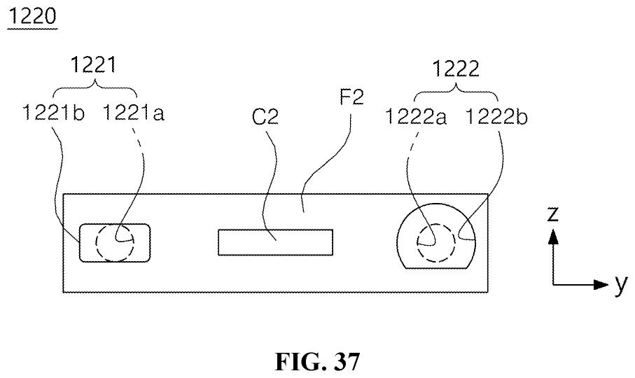

FIG. 32 is a perspective view illustrating a state in which a first housing and a second housing according to a twelfth embodiment of the present invention are separated, FIG. 33 is a side view illustrating the state in which the first housing and the second housing according to the twelfth embodiment of the present invention are separated, FIG. 34 is a top plan view illustrating a state in which the first housing and the second housing according to the twelfth embodiment of the present invention are connected, FIG. 35 is a cross-sectional view taken along line B-B in FIG. 34, FIG. 36 is a front view illustrating the first housing according to the twelfth embodiment of the present invention, and FIG. 37 is a front view illustrating the second housing according to the twelfth embodiment of the present invention.

As illustrated in FIGS. 32 to 37, in the twelfth embodiment of the present invention, a first housing 1210 and a second housing 1220 may be connected by a twelfth connection mechanism.

The twelfth connection mechanism may include an insertion hole 1211, a catching groove 1212, an insertion member 1221, a catching member 1222, and a locking member 1215.

The insertion hole 1211 and the catching groove 1212 may be provided at two opposite sides with the first connector C1 interposed therebetween, and the first connector C1 may be provided on the first opposing surface F1 of the first housing 1210.

The insertion hole 1211 may include a first insertion hole 1211a and a second insertion hole 1211b. The first insertion hole 1211a and the second insertion hole 1211b are provided in the first opposing surface F1 and sequentially formed in a direction toward the inside of the first housing 1210. The first insertion hole 1211a and the second insertion hole 1211b are connected to each other. The first insertion hole 1211a and the second insertion hole 1211b may be provided concentrically.

For example, the first insertion hole 1211a may be provided in the form of a long hole elongated in an upward direction (z-axis direction) from a lower portion of the first opposing surface F1. The second insertion hole 1211b may have a circular shape.

The catching groove 1212 may be provided in the form of a concave groove in a direction from a bottom surface of the first housing 1210 toward an upper surface of the first housing 1210. The catching groove 1212 may include a first catching groove 1212a and a second catching groove 1212b.

At least one of the left and right surfaces of the first catching groove 1212a may be configured as an inclined surface SL. The inclined surface SL may have an inclined structure having a width that decreases in the direction (z-axis direction) from the bottom surface of the first housing 1210 toward the upper surface of the first housing 1210.

A first catching member 1222a of the catching member 1222, which is inserted into the first catching groove 1212a, may be accurately inserted into the first catching groove 1212a along the inclined surface SL.

The second catching groove 1212b may be configured as a groove larger than the first catching groove 1212a. A second catching member 1222b of the catching member 1222 may be inserted into the second catching groove 1212b.

The insertion member 1221 and the catching member 1222 may be provided at two opposite sides with the second connector C2 interposed therebetween, and the second connector C2 may be provided on the second opposing surface F2 of the second housing 1220.

The insertion member 1221 may include a first insertion member 1221a and a second insertion member 1221b.

The first insertion member 1221a may be positioned in the first insertion hole 1211a when the insertion member 1221 is inserted into the insertion hole 1211.

The second insertion member 1221b is provided at an end of the first insertion member 1221a. The second insertion member 1221b may be formed in a shape that conforms to the first insertion hole 1211a so that the second insertion member 1221b may be inserted into the first insertion hole 1211a.

The second insertion member 1221b may be inserted into the second insertion hole 1211b through the first insertion hole 1211a. The second insertion member 1221b rotates in the second insertion hole 1211b so as to intersect the first insertion hole 1211a. When the second insertion member 1221b intersects the first insertion hole 1211a, the second insertion member 1221b cannot be withdrawn through the first insertion hole 1211a.

When the second housing 1220 is pulled in the state in which the second insertion member 1221b intersects the first insertion hole 1211a, the second insertion member 1221b is caught by the first insertion hole 1211a, such that the first housing 1210 and the second housing 1220 cannot be separated.

The catching member 1222 may include the first catching member 1222a and the second catching member 1222b.

When the catching member 1222 rotates in the direction from the bottom surface of the first housing 1210 toward the upper surface of the first housing 1210 about the insertion member 1221 inserted into the insertion hole 1211, the first catching member 1222a may be inserted into the first catching groove 1212a, and the second catching member 1222b may be inserted into the second catching groove 1212b.

The second catching member 1222b is provided at an end of the first catching member 1222a. For example, the second catching member 1222b may have a circular shape capable of being inserted into the second catching groove 1212b.

The second catching member 1222b has a flat surface portion FS. The flat surface portion FS is directed toward the bottom surface of the first housing 1210 in the state in which the second catching member 1222b is inserted into the second catching groove 1212b. The second catching member 1222b may be locked in a state in which the flat surface portion FS is supported by the locking member 1215.

The locking member 1215 is inserted into a guide hole 1213. The guide hole 1213 may be provided in the first housing 1210 and formed in the direction intersecting the second catching groove 1212b so as to communicate with the second catching groove 1212b.

One end of the locking member 1215 is inserted into the guide hole 1213 and elastically supported by an elastic member 1214. The other end of the locking member 1215 supports the flat surface portion FS of the second catching member 1222b inserted into the second catching groove 1212b, thereby implementing the locked state.

The locking member 1215 may prevent the second catching member 1222b, which is inserted into the second catching groove 1212b, from being withdrawn from the second catching groove 1212b.

The locking member 1215 is connected to a locking adjustment device 1217. The locking adjustment device 1217 may move the locking member 1215 in the locking direction while moving along an operating space 1216 provided in the first housing 1210. For example, the locking adjustment device 1217 may be a lever, a switch, a button, or the like.

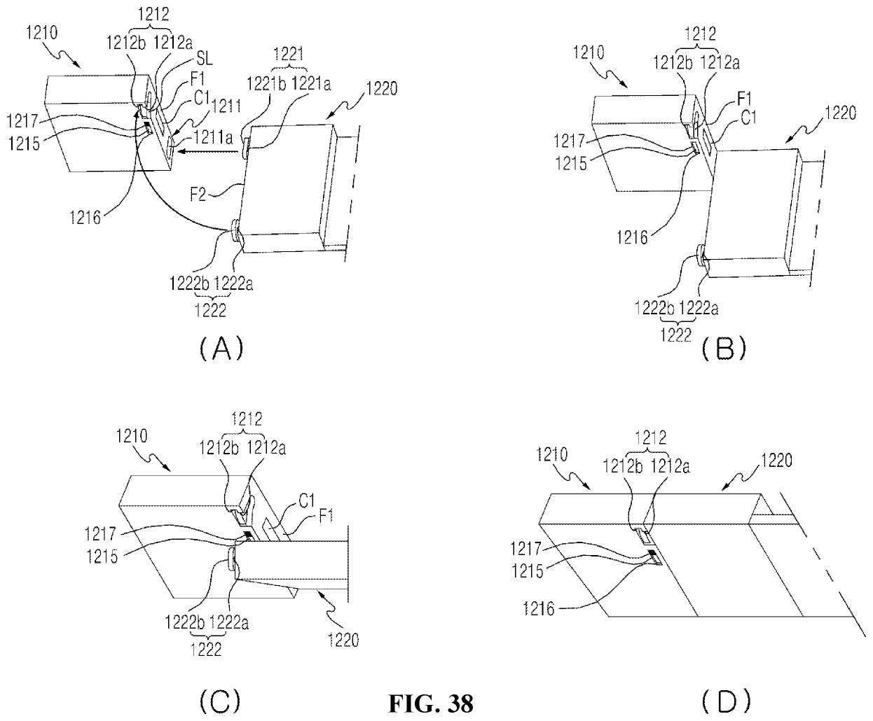

FIG. 38 is a view illustrating a process of connecting the first housing and the second housing according to the twelfth embodiment of the present invention.

As illustrated in FIG. 38A, the second insertion member 1221b of the insertion member 1221 is consistent with the first insertion hole 1211a of the first housing 1210 in order to insert the insertion member 1221 of the second housing 1220 into the insertion hole 1211 of the first housing 1210.

As illustrated in FIG. 38B, the second insertion member 1221b may be inserted into the second insertion hole 1211b through the first insertion hole 1211a in the state in which the second insertion member 1221b of the second housing 1220 is consistent with the first insertion hole 1211a of the first housing 1210.

As illustrated in FIGS. 38C and 38D, in the state in which the insertion member 1221 of the second housing 1220 is inserted into the insertion hole 1211 of the first housing 1210, the second housing 1220 is rotated about the insertion member 1221, such that the catching member 1222 is inserted into the catching groove 1212 while rotating in the direction from the bottom surface of the first housing 1210 toward the upper surface of the first housing 1210.

When the catching member 1222 is inserted into the catching groove 1212, the first catching member 1222a may be inserted into the first catching groove 1212a by being guided by the inclined surface SL, and the second catching member 1222b may be inserted into the second catching groove 1212b (see FIG. 34).

During the process of rotating the second housing 1220 about the insertion member 1221, the second insertion member 1221b may intersect the first insertion hole 1211a (see FIG. 35).

When the second catching member 1222b is inserted into the second catching groove 1212b in the state in which the other end of the locking member 1215 is positioned in the second catching groove 1212b, the second catching member 1222b is caught by the other end of the locking member 1215, such that the second catching member 1222b cannot be inserted into the second catching groove 1212b. When the second catching member 1222b is inserted into the second catching groove 1212b, the locking adjustment device 1217 may be pulled, and the second catching member 1222b may be inserted into the second catching groove 1212b in the state in which the locking member 1215 connected to the locking adjustment device 1217 is completely inserted into the guide hole 1213 while compressing the elastic member 1214 (see FIG. 35).

As illustrated in FIG. 35, when the force, which pulls the locking adjustment device 1217, is eliminated in the state in which the second catching member 1222b is inserted into the second catching groove 1212b, the compressed elastic member 1214 may be extended, and the locking member 1215 may be pushed toward the second catching groove 1212b by the elastic member 1214.

As the locking member 1215 is pushed toward the second catching groove 1212b, the other end of the locking member 1215 may support the flat surface portion FS of the second catching member 1222b inserted into the second catching groove 1212b, such that the locked state of the catching member 1222 may be implemented.

As described above, in the twelfth embodiment of the present invention, the first housing 1210 and the second housing 1220 may be securely connected by the connection structure such as the insertion member 1221 and the catching member 1222 of the second housing 1220, which are inserted into the insertion hole 1211 and the catching groove 1212 of the first housing 1210, and the locking member 1215 configured to lock the catching member 1222.

The above description is simply given for illustratively describing the technical spirit of the present invention, and those skilled in the art to which the present invention pertains will appreciate that various modifications, changes, and substitutions are possible without departing from the essential characteristic of the present invention. Accordingly, the embodiments disclosed in the present invention and the accompanying drawings are intended not to limit but to describe the technical spirit of the present invention, and the scope of the technical spirit of the present invention is not limited by the embodiments and the accompanying drawings. The protective scope of the present invention should be construed based on the following claims, and all the technical spirit in the equivalent scope thereto should be construed as falling within the scope of the present invention.

As described above, the exemplary embodiments have been described and illustrated in the drawings and the specification. The exemplary embodiments were chosen and described in order to explain certain principles of the invention and their practical application, to thereby enable others skilled in the art to make and utilize various exemplary embodiments of the present invention, as well as various alternatives and modifications thereof. As is evident from the foregoing description, certain aspects of the present invention are not limited by the particular details of the examples illustrated herein, and it is therefore contemplated that other modifications and applications, or equivalents thereof, will occur to those skilled in the art. Many changes, modifications, variations and other uses and applications of the present construction will, however, become apparent to those skilled in the art after considering the specification and the accompanying drawings. All such changes, modifications, variations and other uses and applications which do not depart from the spirit and scope of the invention are deemed to be covered by the invention which is limited only by the claims which follow.

What is claimed is:

1. A bendable detector comprising:
a first housing comprising a control unit therein and made of an inelastic material or a material having higher rigidity than a material of a second housing;
the second housing comprising a detection panel therein and made of an elastic material or composite material including an elastic material and an inelastic material; and
a connection mechanism having a connection structure configured to couple the first housing and the second housing so that the first housing and the second housing are separable.

2. The bendable detector of claim 1, comprising:
a first connector provided on a first opposing surface of the first housing; and
a second connector provided on a second opposing surface of the second housing and configured to be connected to the first connector.

3. The bendable detector of claim 2, wherein any one of the first and second connectors is a connector having a pogo pin, and the other of the first and second connectors is a connector to which the pogo pin is connected.

4. The bendable detector of any one of claim 1, wherein the connection mechanism is a first connection mechanism comprising:
an insertion member protruding from one side or two opposite sides of the first opposing surface of the first housing toward the second opposing surface of the second housing; and
an insertion hole provided in a portion of the second opposing surface of the second housing corresponding to the insertion member so that the insertion member is inserted into the insertion hole.

5. The bendable detector of any one of claim 1, wherein the connection mechanism is a first connection mechanism comprising:
an insertion member protruding from one side or both sides of the second opposing surface of the second housing toward the first opposing surface of the first housing; and
an insertion hole provided in a portion of the first opposing surface of the first housing corresponding to the insertion member so that the insertion member is inserted into the insertion hole.

6. The bendable detector of claim 4, wherein the first connection mechanism comprises a locking member configured to prevent the first and second housings from being disconnected, a guide hole is formed in the second housing in a direction intersecting the insertion hole, one end of the locking member is elastically supported by an elastic member provided in the guide hole, the other end of the locking member is inserted into an insertion groove provided in the insertion member and restricts a movement of the insertion member, and a locking adjustment device connected to the locking member moves the locking member while moving along an operating space provided in the second housing.

7. The bendable detector of any one of claim 1, wherein the connection mechanism is a second connection mechanism comprising:
an insertion member protruding from one side or two opposite sides of the first opposing surface of the first housing toward the second opposing surface of the second housing; and
an insertion groove provided in a lateral surface of the second housing corresponding to the insertion member and formed in a longitudinal direction so that the insertion member is inserted into the insertion groove.

8. The bendable detector of any one of claim 1, wherein the connection mechanism is a third connection mechanism comprising:
an insertion member protruding from one side or two opposite sides of the first opposing surface of the first housing toward the second opposing surface of the second housing; and
an insertion groove formed in a portion of the second opposing surface of the second housing corresponding to the insertion member so that the insertion member is slidably inserted into the insertion groove.

9. The bendable detector of claim 8, wherein the insertion member and the insertion groove each have a shape such as a “└” shape or a “⊏” shape.

10. The bendable detector of any one of claim 1, wherein the connection mechanism comprises an insertion member configured to prevent the first and second housings from being disconnected, the insertion member comprises an extension portion protruding from one side or two opposite sides of the first opposing surface of the first housing toward the second opposing surface of the second housing, and a locking member provided at an end of the extension portion, an insertion groove is provided in a portion of the second opposing surface of the second housing corresponding to the insertion member, the insertion member is inserted into the insertion groove, a locking adjustment device connected to the extension portion is provided, the locking adjustment device is accommodated in an accommodation portion of the first housing, at least a part of the locking adjustment device is exposed to the outside of the accommodation portion, and the locking adjustment device rotates to rotate the locking member in a locking direction, in a state in which the insertion member is inserted into the insertion groove, so that the locking member intersects the insertion groove.

11. The bendable detector of any one of claim 1, wherein the connection mechanism is a fifth connection mechanism comprising:
a locking member provided on one side surface or two opposite surfaces of the first housing and comprising an extension portion having one end connected to the first housing by a hinge shaft, the extension portion being configured to rotate about the hinge shaft and elastically supported by an elastic member coupled to the hinge shaft, and a catching projection provided at the other end of the extension portion; and
an insertion groove provided in a lateral surface of the second housing corresponding to the locking member and formed in a longitudinal direction so that the extension portion is inserted into the insertion groove.

12. The bendable detector of claim 11, wherein the catching projection is inserted into a catching groove provided in the insertion groove.

13. The bendable detector of claim 11, wherein the fifth connection mechanism further comprises:
an insertion member provided between the locking members disposed at two opposite sides, the insertion member protruding from one side or two opposite sides of the first opposing surface of the first housing toward the second opposing surface of the second housing; and
an insertion hole provided in a portion of the second opposing surface of the second housing corresponding to the insertion member so that the insertion member is inserted into the insertion hole.

14. The bendable detector of any one of claim 1, wherein the connection mechanism is a sixth connection mechanism having a connection member coupled while penetrating the first and second housings in a state in which the first and second housings are disposed side by side horizontally in a longitudinal direction.

15. The bendable detector of any one of claim 1, wherein the connection mechanism is a seventh connection mechanism having a connection member coupled while penetrating the first and second housings in a state in which the first and second housings are arranged vertically.

16. The bendable detector of claim 15, wherein the seventh connection mechanism further comprises:
a sliding groove provided in a lower portion of the first housing; and
a sliding rail provided on an upper portion of the second housing so as to conform to the sliding groove and slidably inserted into the sliding groove.

17. The bendable detector of any one of claim 1, wherein the connection mechanism is an eighth connection mechanism in which connection plates configured to connect the first housing and the second housing are attached to two opposite sides of the first housing and two opposite sides of the second housing in a state in which the first and second housings are disposed side by side horizontally in a longitudinal direction or arranged vertically, first connection members are coupled to the first housing while penetrating the connection plates, and second connection members are coupled to the second housing while penetrating the connection plates.

18. The bendable detector of any one of claim 1, wherein the connection mechanism is a ninth connection mechanism comprising:
a sliding groove provided in a lower portion of the first housing and formed in a longitudinal direction; and
a sliding rail provided on an upper portion of the second housing and formed in the longitudinal direction, the sliding rail conforming to the sliding groove so that the sliding rail is slidably inserted into the sliding groove.

19. The bendable detector of claim 18, wherein the ninth connection mechanism further comprises:
a guide hole provided in the first housing and formed in a direction intersecting the sliding groove;
a locking member having one end elastically supported by an elastic member inserted into the guide hole, and the other end inserted into a insertion groove provided in the sliding rail; and
a locking adjustment device connected to the locking member and configured to move the locking member while moving along an operating space provided in the first housing.

20. The bendable detector of claim 1, wherein the connection mechanism is a tenth connection mechanism comprising:
a sliding rail provided on one longitudinal surface of the first housing and formed in a direction intersecting a longitudinal direction of the first housing; and
a sliding groove provided in one longitudinal surface of the second housing and formed in a direction intersecting a longitudinal direction of the second housing so that the sliding rail is inserted into the sliding groove.

21. The bendable detector of claim 20, wherein a first opposing surface, on which a first connector is provided, is provided on a surface that enters the sliding groove of the sliding rail, and a second opposing surface, on which a second connector is provided, is provided on an inner end surface of the sliding groove corresponding to the first opposing surface.

22. The bendable detector of claim 21, wherein the first opposing surface is provided in the direction intersecting the longitudinal direction of the first housing, and the second opposing surface is provided in the direction intersecting the longitudinal direction of the second housing.

23. The bendable detector of claim 22, wherein the first connector is provided in the direction intersecting the longitudinal direction of the first housing, and the second connector is provided in the direction intersecting the longitudinal direction of the second housing.

24. The bendable detector of claim 20, wherein a first opposing surface, on which a first connector is provided, is provided in an accommodation groove provided in a longitudinal direction of one surface of the sliding rail, and a second opposing surface, on which a second connector is provided, is provided in the sliding groove while corresponding to the first opposing surface.

25. The bendable detector of claim 24, wherein the first opposing surface is provided in the direction identical to the longitudinal direction of the first housing, and the second opposing surface is provided in the direction identical to the longitudinal direction of the second housing.

26. The bendable detector of claim 25, wherein the first connector is provided in the direction identical to the longitudinal direction of the first housing, and the second connector is provided in the direction identical to the longitudinal direction of the second housing.

27. The bendable detector of claim 21, wherein the first connector and the second connector are each configured as a horizontal connector or an inclined connector.

28. The bendable detector of claim 20, wherein the tenth connection mechanism further comprises:
a guide hole provided in the second housing and configured to communicate with the sliding groove;
a locking member having one end elastically supported by an elastic member provided in the guide hole, and the other end inserted into an insertion groove of the first housing; and
a locking adjustment device connected to the locking member and configured to move the locking member while moving along an operating space provided in the second housing.

29. The bendable detector of claim 1, wherein the connection mechanism is an eleventh connection mechanism comprising:
an assembling groove provided in an upper portion of the first opposing surface of the first housing;
a locking member comprising an extension portion having one end positioned in the first housing, rotatably connected to the first housing by a hinge shaft, and elastically supported by an elastic member, and the other end exposed toward the second housing, and a catching projection provided at the other end of the extension portion;
at least one hook inserted into the assembling groove and provided on a portion of the second opposing surface of the second housing while corresponding to the assembling groove;
an insertion groove formed in a bottom surface of the second housing so that the other end of the extension portion is inserted into the insertion groove; and
a catching groove provided in the insertion groove so that the catching projection is inserted into the catching groove.

30. The bendable detector of claim 1, wherein the connection mechanism is a twelfth connection mechanism comprising:
an insertion hole provided at one side of the first opposing surface of the first housing;
a catching groove provided at the other side of the first opposing surface of the first housing and configured as a concave groove formed in a direction from a bottom surface of the first housing toward an upper surface of the first housing;
an insertion member protruding from one side of the second opposing surface of the second housing toward the first housing and inserted into the insertion hole; and
a catching member protruding from the other side of the second opposing surface of the second housing toward the first housing, the catching member being configured to be inserted into the catching groove while rotating about the insertion member inserted into the insertion hole in the direction from the bottom surface of the first housing toward the upper surface of the first housing.

31. The bendable detector of claim 30, wherein the insertion hole comprises:
a first insertion hole configured as a long hole; and
a second insertion hole configured to communicate with the first insertion hole and provided to be closer to the inside of the first housing than the first insertion hole, the second insertion hole being configured as a hole having the same center as the first insertion hole.

32. The bendable detector of claim 31, wherein the insertion member comprises:
a first insertion member positioned in the first insertion hole when the insertion member is inserted into the insertion hole; and
a second insertion member provided at an end of the first insertion member and having a shape conforming to the first insertion hole, the second insertion member being configured to rotate to intersect the first insertion hole in a state in which the second insertion member is inserted into the second insertion hole through the first insertion hole.

33. The bendable detector of claim 30, wherein the catching groove comprises:
a first catching groove; and
a second catching groove configured to communicate with the first catching groove and provided to be closer to the inside of the second housing than the first catching groove, the second catching groove being configured as a groove larger than the first catching groove.

34. The bendable detector of claim 33, wherein at least one lateral surface of the first catching groove is configured as an inclined surface, and the inclined surface has an inclined structure having a width that decreases in the direction from the bottom surface of the first housing toward the upper surface of the first housing.

35. The bendable detector of claim 33, wherein the catching member comprises:
a first catching member positioned in the first catching groove when the catching member is inserted into the catching groove; and
a second catching member provided at an end of the first catching member and configured such that a portion of the second catching member, which is directed toward the bottom surface of the first housing in a state in which the second catching member is inserted into the second catching groove, is configured as a flat surface portion.

36. The bendable detector of claim 35, further comprising:
a guide hole provided in the first housing and formed in a direction intersecting the second catching groove so as to communicate with the second catching groove;
a locking member having one end inserted into the guide hole and elastically supported by an elastic member, and the other end configured to support the flat surface portion of the second catching member inserted into the second catching groove to implement a locked state; and
a locking adjustment device connected to the locking member and configured to move the locking member in a locking direction while moving along an operating space provided in the first housing.
